(19) United States
(12) Patent Application Publication
(10) Pub. No.: US 2026/0206528 A1
(43) Pub. Date: Jul. 16, 2026

(54) SEMICONDUCTOR PROCESSING TOOL AND METHODS OF OPERATION

(71) Applicant: Taiwan Semiconductor Manufacturing Company, Ltd., Hsinchu (TW)

(72) Inventors: Hau-Yi HSIAO, Chiayi City (TW); Kuo-Ming WU, Tainan City (TW); Sheng-Chau CHEN, Tainan City (TW); Chung-Yi YU, Hsin-Chu (TW); Cheng-Yuan TSAI, Chu-Pei City (TW); Min-Chang CHING, Tainan (TW)

(21) Appl. No.: 19/018,215

(22) Filed: Jan. 13, 2025

(51) Int. Cl. H01L 21/67; B08B 1/20; H01L 21/66

(52) U.S. Cl. CPC H10P 72/0616; B08B 1/20; H10P 72/0441; H10P 74/23

(57) ABSTRACT

A semiconductor processing tool includes one or more devices that are configured to inspect sealant dispensed into and/or around a groove around a wafer stack. The one or more devices may be used to determine whether a sufficient amount of sealant is dispensed into the groove and/or whether errant sealant particles landed on the top and/or bottom surfaces of the wafer stack. This enables the semiconductor processing tool to cause a reseal operation to be performed to dispense additional sealant into the groove if an insufficient amount of sealant was dispensed into the groove, and/or enables the semiconductor processing tool to cause a cleaning operation to be performed to clean the top and/or bottom surfaces of the wafer stack.

### BACKGROUND

A three-dimensional integrated circuit (3DIC) assembly may include two or more integrated circuit (IC) dies that are stacked vertically and bonded along a bonding interface. The 3DIC assembly may be formed by stacking two or more semiconductor substrates, each including a subset of the two or more IC dies, using a wafer bonding operation such as a wafer-on-wafer (WoW) bonding operation. After the bonding operation, the 3DIC assembly including the two or more IC dies may be diced from the stack of two or more semiconductor substrates and encapsulated in a semiconductor die package.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor processing tool described herein.

FIG. 2 is a diagram of an example implementation of a semiconductor processing tool described herein.

FIGS. 3A-3F are diagrams of an example implementation of an edge sealing operation described herein.

FIGS. 4A and 4B are diagrams of an example implementation of an edge sealing inspection operation described herein.

FIGS. 5A-5F are diagrams of an example implementation of an edge sealing rework operation described herein.

FIGS. 6A-6F are diagrams of an example implementation of an edge sealing rework operation described herein.

FIG. 7 is a diagram of an example implementation of a scrubber device described herein.

FIGS. 8A-8D are diagrams of an example implementation of an edge sealing operation described herein.

FIG. 9 is a diagram of example components of a device described herein.

FIG. 10 is a flowchart of an example process associated with performing an edge sealing operation described herein.

FIG. 11 is a flowchart of an example process associated with performing an edge sealing operation described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a partially completed wafer stack of substrates (e.g., semiconductor wafers or another type of wafers) used to form a stacked integrated circuit die product may include a groove that corresponds to a beveled region around a perimeter of the wafer stack. The groove may be located between edges of the substrates in the wafer stack, and may occur because of incomplete bonding of the edges of the substrates and/or because of the edges of the substrates having a curvature, among other examples. In some cases, the groove around the perimeter of the wafer stack is filled with a sealant. The sealant prevents or reduces the likelihood of ingress of contaminants such as humidity, hydrogen, and/or oxygen from being exposed to the substrates through the groove. The sealant may also provide increased structural stability around the perimeter of the wafer stack, and may prevent or reduce the likelihood of cracking and/or delamination of the substrates that might otherwise originate at the groove. The sealant may be dispensed into the groove around the wafer stack using a wafer edge sealing tool. The wafer stack may be placed on a chuck in a processing chamber of the wafer edge sealing tool, and an injector nozzle of the wafer edge sealing tool may dispense the sealant into the groove around the wafer stack as the chuck is used to rotate the wafer stack.

An amount of the sealant dispensed within the groove can impact the edge sealing performance of the sealant and can impact the yield of wafer stacks during manufacturing. For example, if the amount of the sealant dispensed into the groove is too little, a risk of delamination starting in the groove may be increased. Alternatively, if the amount of the sealant dispensed into the groove is too much, a risk of the sealant flowing out of the groove or splattering off of the edges of the substrates may increase. This may result in errant sealant particles (e.g., sealant particles that do not remain in the groove, sealant particles that correspond to overspray of the sealant that is dispensed in areas around the wafer stack) landing on the top and/or bottom surfaces of the wafer stack and causing defects in subsequent processing operations. These defects can go undetected for days until identified during a later inspection time, and the delay in detection of these defects can significantly increase rework time and/or decrease the likelihood that a wafer stack can be saved through rework.

In some implementations described herein, a sealant inspection system for use with a wafer edge sealing tool includes one or more devices that are configured to inspect the sealant dispensed into and/or around the groove around a wafer stack. The sealant inspection system may determine whether a sufficient amount of sealant is dispensed into the groove and/or whether errant sealant particles landed on the top and/or bottom surfaces of the wafer stack. This enables the sealant inspection system to cause a re-seal operation to be performed to dispense additional sealant into the groove if an insufficient amount of sealant was dispensed into the groove, and/or enables the sealant inspection system to cause a cleaning operation to be performed to clean the top and/or bottom surfaces of the wafer stack. In this way, the sealant inspection system prevents, minimizes, and/or otherwise reduces the likelihood of delamination of the wafer stack and/or errant sealant particles causing defects in subsequent processing operations. Moreover, the sealant inspection system enables rework of the wafer stack to be performed in a more timely manner, thereby reducing processing delays for the wafer stack and/or increasing the likelihood that the wafer stack can be saved from being scrapped.

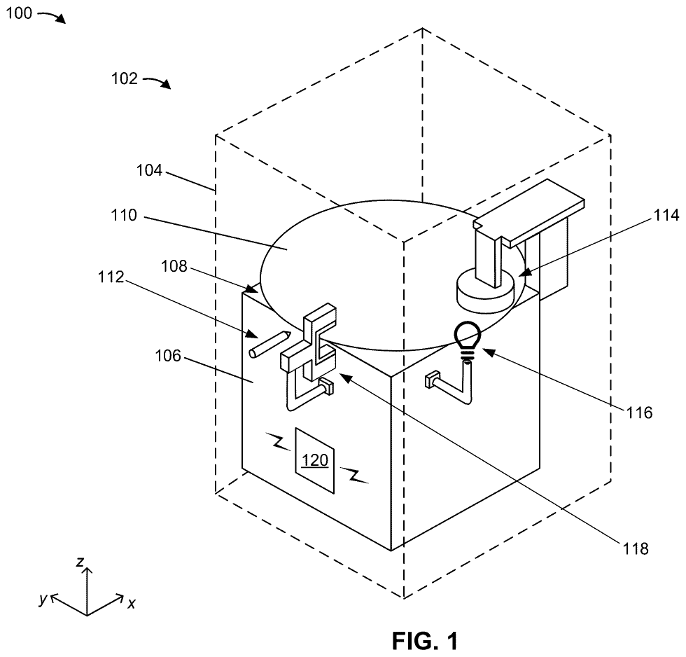

FIG. 1 is a diagram of an example implementation 100 of a semiconductor processing tool 102 described herein. The semiconductor processing tool 102 includes a wafer edge sealing tool or another type of semiconductor processing tool that is configured to dispense a sealant in a groove around a perimeter of a wafer stack.

As shown in a perspective view in FIG. 1, the semiconductor processing tool 102 may include a processing chamber 104 and a stage 106 within the processing chamber 104. The stage 106 may correspond to a housing in which various systems, subsystems, and/or devices, of the semiconductor processing tool 102 are located, such as plumbing, pumps, electrical systems, controllers, actuators such as motors, and/or other components. The stage 106 may also support a chuck 108 of the semiconductor processing tool 102. The chuck 108 may be located within the processing chamber 104 and may be configured to support a wafer stack 110. The wafer stack 110 is a workpiece that is not a part of the semiconductor processing tool 102, and instead may be positioned on the chuck 108 for processing. The chuck 108 may secure the wafer stack 110 in place using a vacuum force (in implementations in which the chuck 108 is a vacuum chuck), an electrostatic force (in implementations in which the chuck 108 is an electrostatic chuck (ESC)), and/or another type of force.

The wafer stack 110 is secured to the chuck 108 so that the chuck 108 can rotate the wafer stack 110 in a secure manner while an injector nozzle 112 of the semiconductor processing tool 102 injects a sealant into a groove around the edge of the wafer stack 110. Rotating the wafer stack 110 in an x-y plane while injecting the sealant along an x-direction and/or along a y-direction into the groove enables the sealant to be dispensed around the full circumference or perimeter of the wafer stack 110. In some implementations, the chuck 108 is configured to rotate the wafer stack 110 at a rate of approximately 50 degrees per second to approximately 70 degrees per second. However, other values and ranges are within the scope of the present disclosure.

In some implementations, the injector nozzle 112 may be coupled to a pump system (e.g., that may be included in the stage 106 or external to the processing chamber 104) having an adjustable pressure and/or dispense rate. This enables the dispensing rate of sealant to be adjusted. Furthermore, and in some implementations, the injector nozzle 112 is coupled to a positioning system that can be used to adjust an aim point of the injector nozzle 112 for dispensing sealant. In some implementations, the aim point of the injector nozzle 112 is adjustable in a z-direction (e.g., a vertical direction). In some implementations, the aim point of the injector nozzle 112 is adjustable in an x-direction and/or in a y-direction (e.g., a lateral direction).

In some implementations, the injector nozzle 112 may be positioned approximately 1 millimeter to approximately 2 millimeters away from the edge of the wafer stack 110. However, other values and ranges are within the scope of the present disclosure. In some implementations, the injector nozzle 112 may be configured to dispense sealant at a frequency of approximately 10 microseconds to approximately 15 microsections. However, other values and ranges are within the scope of the present disclosure. In some implementations, injector nozzle 112 may be configured to dispense sealant at a rate of approximately 7 micrograms per degree of turn to approximately 8 micrograms per degree of turn. However, other values and ranges are within the scope of the present disclosure.

As further shown in FIG. 1, an optical inspection device 114 may be included in and/or mounted to the processing chamber 104. The optical inspection device 114 may include a camera device that is configured to generate images and/or video for inspecting the perimeter of a wafer stack 110 for an edge sealing operation performed in the processing chamber 104 of the semiconductor processing tool 102. The optical inspection device 114 may include an infrared (IR) camera, a charge coupled device (CCD) camera, a complementary metal-oxide-semiconductor (CMOS) image sensor, and/or another type of camera device.

The optical inspection device 114 may be used to inspect the perimeter of a wafer stack 110 prior to, during, and/or after an edge sealing operation performed to dispense sealant into a groove around the perimeter of a wafer stack 110. For example, the optical inspection device 114 may be used to inspect the groove around the perimeter of the wafer stack 110, the top surface of the wafer stack 110 around the perimeter of the wafer stack 110, and/or the bottom surface of the wafer stack 110 around the perimeter of the wafer stack 110, among other examples. In some implementations, the optical inspection device 114 is used to inspect the groove around the perimeter of the wafer stack 110 for verification that a sufficient amount of sealant was dispensed into the groove around the perimeter of the wafer stack 110. In some implementations, the optical inspection device 114 is used to inspect the top and/or bottom surfaces around the perimeter of the wafer stack 110 for identifying errant sealant particles that have splashed onto the top and/or bottom surfaces around the perimeter of the wafer stack 110 (referred to as backsplash).

The optical inspection device 114 may be positioned above the chuck 108 (e.g., so that the optical inspection device 114 is located above a wafer stack 110 positioned on the chuck 108) and/or below the chuck 108 (e.g., so that the optical inspection device 114 is located under a wafer stack 110 positioned on the chuck 108). In some implementations, the optical inspection device 114 is secured to an articulating support arm that enables the optical inspection device 114 to be rotated about the perimeter of the wafer stack 110. The optical inspection device 114 may be supported by a support arm that is attached to the stage 106, to the processing chamber 104, and/or to another location that permits the chuck 108 to freely rotate the wafer stack 110 while the optical inspection device 114 generates images and/or video of the perimeter of the wafer stack 110.

As further shown in FIG. 1, a light source 116 may be positioned adjacent to the chuck 108 so that the light source 116 is adjacent to the perimeter of a wafer stack 110 positioned on the chuck 108. The light source 116 may be configured to emit light to illuminate the perimeter of the wafer stack 110. The light emitted from the light source 116 may enhance the images and/or video generated by the optical inspection device 114 in that the light emitted from the light source 116 provides for a great amount of light that may be sensed by the optical inspection device 114. This enables the optical inspection device 114 to generate images and/or video that have higher contrast between light areas and dark areas, which enables a greater amount of detail of the contours and other features of the perimeter of the wafer stack 110 to be viewed in the images and/or video.

In some implementations, the light source 116 is configured to emit a particular wavelength range of light that is based on the wavelength range across which the optical inspection device 114 is configured to sense. For example, the optical inspection device 114 may be configured to sense infrared light in a wavelength range associated with infrared light, and the light source 116 may emit light in the wavelength range associated with infrared light. In some implementations, the light source 116 may emit light in a wavelength range of approximately 800 nanometers to approximately 1300 nanometers to achieve a high amount of illumination of dark areas of the perimeter of the wafer stack 110 and/or to achieve a high contrast between light areas and dark areas of the perimeter of the wafer stack 110. However, other values and ranges are within the scope of the present disclosure.

The light source 116 may be positioned above the chuck 108 (e.g., so that the light source 116 is located above a wafer stack 110 positioned on the chuck 108) and/or below the chuck 108 (e.g., so that the light source 116 is located under a wafer stack 110 positioned on the chuck 108). In some implementations, the light source 116 is secured to an articulating support arm that enables the light source 116 to be rotated about the perimeter of the wafer stack 110. This enables the contours and features of the perimeter of the wafer stack 110 to be dynamically illuminated to enhance the level of detail that is captured in images and/or video by the optical inspection device 114. The light source 116 may be supported by a support arm that is attached to the stage 106, to the processing chamber 104, and/or to another location that permits the chuck 108 to freely rotate the wafer stack 110.

In some implementations, the optical inspection device 114 and the light source 116 are positioned adjacent to opposing sides of the wafer stack 110. For example, and as shown in FIG. 1, the optical inspection device 114 may be positioned above the wafer stack 110, and the light source 116 may be positioned below the wafer stack 110. In these implementations, the optical inspection device 114 generates images and/or video based on transmission of light emitted by the light source 116 through the perimeter of the wafer stack 110. Thus, the intensity of light sensed at the optical inspection device 114 may be based on the contours and features of the perimeter of the wafer stack 110 through which the light is transmitted.

In some implementations, the optical inspection device 114 and the light source 116 are positioned adjacent to the same side of the wafer stack 110. For example, the optical inspection device 114 and the light source 116 may both be positioned above the wafer stack 110. In these implementations, the optical inspection device 114 generates images and/or video based on reflection of light emitted by the light source 116 off of the perimeter of the wafer stack 110.

As further shown in FIG. 1, a scrubber device 118 may be positioned adjacent to the chuck 108 so that the scrubber device 118 is adjacent to the perimeter of a wafer stack 110 positioned on the chuck 108. The scrubber device 118 may be configured to scrub or otherwise clean the top and/or bottom surfaces of a wafer stack 110 at the perimeter of the wafer stack 110. In other words, the scrubber device 118 may be configured to remove errant sealant particles that have splashed onto the top and/or bottom surfaces of a wafer stack 110 at the perimeter of the wafer stack 110. Such splashing may occur, for example, where sealant is dispensed into the groove around the perimeter of the wafer stack 110, and some of the sealant back splashes off of the groove and lands onto the top and/or bottom surfaces of a wafer stack 110. If left on the top and/or bottom surfaces of a wafer stack 110, these errant particles might otherwise interfere with subsequent processing steps for the wafer stack 110 (e.g., with wafer grinding operations), thus leading to an increased likelihood of defect formation in the wafer stack 110.

The scrubber device 118 may include a cleaning pad, a cleaning cloth, and/or another type of cleaning device that can mechanically remove errant sealant particles from the top and/or bottom surfaces of a wafer stack 110 with minimal to no damage to the wafer stack 110. The cleaning device of the scrubber device 118 may be non-abrasive and may have a soft texture so that the cleaning device conforms to the shape and/or contours of the perimeter of the wafer stack 110.

The scrubber device 118 may be supported by a support arm that is attached to the stage 106, to the processing chamber 104, and/or to another location that permits the chuck 108 to freely rotate the wafer stack 110. The support arm may be articulating in that the support arm is configured to move the scrubber device 118 toward and/or away from the chuck 108.

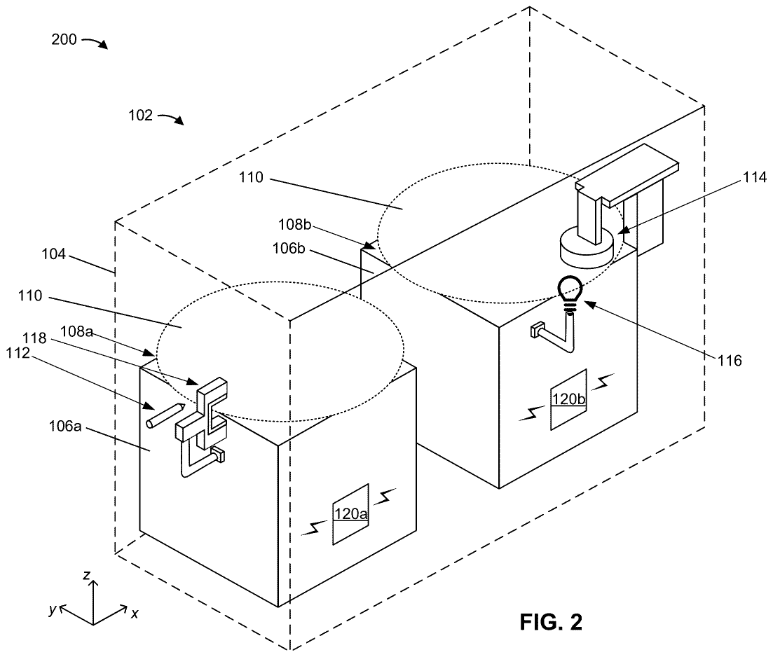

As shown in the example in FIG. 1, the injector nozzle 112, the optical inspection device 114, the light source 116, and the scrubber device 118 may be positioned around the same chuck 108 on the same stage 106. Thus, the example implementation 100 of the semiconductor processing tool 102 includes a combined (or integrated) dispensing and inspection stage on which dispensing of sealant and inspection (and rework) of the dispensed sealant occurs on the same chuck 108 and the same stage 106. FIG. 2 includes an example implementation of the semiconductor processing tool 102 in which the semiconductor processing tool 102 is a multiple-stage tool that includes separate stages for dispensing of sealant and for inspection (and rework) of the dispensed sealant.

In some implementations, two or more of the injector nozzle 112, the optical inspection device 114, the light source 116, and the scrubber device 118 may be positioned adjacent to a same side of the stage 106. For example, the injector nozzle 112 and the scrubber device 118 may be positioned adjacent to the same side of the stage 106, and/or the optical inspection device 114 and the light source 116 may be positioned adjacent to the same side of the stage 106. In some implementations, two or more of the injector nozzle 112, the optical inspection device 114, the light source 116, and the scrubber device 118 may be positioned adjacent to different sides of the stage 106. For example, the injector nozzle 112 and the optical inspection device 114 may be positioned adjacent to the different sides of the stage 106, and/or the light source 116 and the scrubber device 118 may be positioned adjacent to the different sides of the stage 106.

As further shown in FIG. 1, the semiconductor processing tool 102 may include a controller 120. The controller 120 (e.g., a processor, a combination of a processor and memory, among other examples) may be communicatively coupled to one or more components of the semiconductor processing tool 102, such as electrical sources, mass flow controllers, vacuum pumps, compressors, the chuck 108, the injector nozzle 112, the optical inspection device 114, the light source 116, the scrubber device 118, one or more of the support arms (e.g., that support the injector nozzle 112, the optical inspection device 114, the light source 116, and/or the scrubber device 118), and/or a wafer/die transport tool (e.g., a robot arm) of the semiconductor processing tool 102, among other examples. The controller 120 may communicate with these components on one or more wireless communication links, one or more wired communication links, and/or a combination of wireless and wired communication links.

The controller 120 may be configured to control one or more aspects of the operation of the semiconductor processing tool 102. For example, the controller 120 may be configured to provide signals to the chuck 108 to cause the chuck 108 to rotate a wafer stack 110 positioned on the chuck 108. As another example, the controller 120 may be configured to provide signals to one or more pumps to cause a sealant to be dispensed through the injector nozzle 112 and into a groove around a perimeter of a wafer stack 110 positioned on the chuck 108 (e.g., while the chuck 108 rotates the wafer stack 110).

As another example, the controller 120 may be configured to provide signals to the light source 116 to cause the light source 116 to emit light around a perimeter of a wafer stack 110 positioned on the chuck 108 (e.g., while the chuck 108 rotates the wafer stack 110). As another example, the controller 120 may be configured to provide signals to the optical inspection device 114 to cause the optical inspection device 114 to inspect the perimeter of the wafer stack 110 (e.g., to generate images and/or video of the perimeter of the wafer stack 110 while the chuck 108 rotates the wafer stack 110 and while the light source 116 emits light around the perimeter of the wafer stack 110).

In some implementations, the controller 120 may be configured to provide signals to cause the semiconductor processing tool 102 to perform one or more rework operations for a wafer stack 110 based on inspection of the images and/or video of the perimeter of the wafer stack 110 generated by the optical inspection device 114.

For example, the controller 120 may be configured to provide signals to the injector nozzle 112 to cause the injector nozzle 112 to perform a re-sealing operation to dispense additional sealant into the groove around the perimeter of the wafer stack 110. The controller 120 may provide the one or more signals to the injector nozzle 112 to cause the injector nozzle 112 to perform a re-sealing operation based on determining (e.g., based on the images and/or video) that an insufficient amount of sealant was dispensed into the groove. In this way, the re-sealing operation can be performed to add additional sealant to the groove to reduce, minimize, and/or otherwise prevent delamination from occurring in the wafer stack 110.

As another example, the controller 120 may be configured to provide signals to the scrubber device 118 to cause the scrubber device 118 to perform a perimeter cleaning operation to remove at least a subset of the sealant splash particles from the underside and/or the topside of the wafer stack 110. The controller 120 may provide the scrubber device 118 to cause the scrubber device 118 to perform a perimeter cleaning operation based on identifying (e.g., based on the images and/or video) sealant splash particles on the underside and/or the topside of the wafer stack 110. In this way, the perimeter cleaning operation can be performed to reduce, minimize, and/or otherwise prevent the sealant splash particles from causing defects to occur in subsequent processing operations for the wafer stack 110. The one or more signals may cause an articulating support arm to move the scrubber device 118 toward the perimeter of the wafer stack 110 so that the edge (or perimeter) of the wafer stack 110 is inserted into the scrubber device 118. Moreover, the controller 120 may be configured to provide signals to the chuck 108 to cause the chuck 108 to rotate the wafer stack 110 so that the scrubber device 118 scrubs the perimeter of the wafer stack 110 while the chuck 108 rotates the wafer stack 110.

In some implementations, the controller 120 may be configured to provide signals to cause the semiconductor processing tool 102 to perform a re-inspection operation for the wafer stack 110 after a rework operation is performed for the wafer stack 110. The re-inspection operation may be performed to verify whether a rework operation successfully repaired the wafer stack 110, or whether additional rework is to be performed (e.g., because the rework operation was not successful). For example, the controller 120 may be configured to provide signals to cause the optical inspection device 114 to inspect the rework of the perimeter of the wafer stack 110 (e.g., to generate images and/or video of the perimeter of the wafer stack 110) while the chuck 108 rotates the wafer stack 110 and while the light source 116 emits light around the perimeter of the wafer stack 110.

As indicated above, FIG. 1 is provided as an example. Other examples may differ from what is described with regard to FIG. 1.

FIG. 2 is a diagram of an example implementation 200 of the semiconductor processing tool 102 described herein. As indicated above, in the example implementation 100 of the semiconductor processing tool 102, the injector nozzle 112, the optical inspection device 114, the light source 116, and the scrubber device 118 may be positioned around the same chuck 108 on the same stage 106. Thus, the example implementation 100 of the semiconductor processing tool 102 includes a combined (or integrated) dispensing and inspection stage on which dispensing of sealant and inspection (and rework) of the dispensed sealant occur on the same chuck 108 and the same stage 106.

As shown in FIG. 2, in the example implementation 200 of the semiconductor processing tool 102, the semiconductor processing tool 102 is a multiple-stage tool that includes separate stages 106a (e.g., a sealant stage) and 106b (e.g., an inspection stage) for dispensing of sealant and for inspection of the dispensed sealant, respectively. For example, the injector nozzle 112 and the scrubber device 118 may be positioned adjacent to the stage 106a, and the optical inspection device 114 and the light source 116 may be adjacent to the stage 106b.

The optical inspection device 114 and the light source 116 being positioned to a different stage than the injector nozzle 112 and the scrubber device 118 may reduce the likelihood of the optical inspection device 114 and the light source 116 becoming contaminated by sealant particles. This may extend the time duration between cleanings of the optical inspection device 114 and the light source 116, and may enable the performance of the optical inspection device 114 and the light source 116 to be sustained for longer durations of time.

However, positioning the injector nozzle 112, the optical inspection device 114, the light source 116, and the scrubber device 118 around the same chuck 108 on the same stage 106 as in the example implementation 100 of the semiconductor processing tool 102 reduces the complexity of the semiconductor processing tool 102 and enables the semiconductor processing tool 102 to fit into a smaller lateral footprint.

Thus, a wafer stack 110 may be positioned on a chuck 108a of the stage 106a for dispensing of sealant into a groove around the wafer stack 110. A controller 120a may be configured to cause the chuck 108a to rotate the wafer stack 110 while the injector nozzle 112 (positioned adjacent to the stage 106a) dispenses sealant into the groove around the perimeter of the wafer stack 110.

The wafer stack 110 may then be transferred from the chuck 108a to a chuck 108b on the stage 106b (e.g., using a wafer/die transport tool of the semiconductor processing tool 102 such as a robot arm). The perimeter of the wafer stack 110 (including the groove and the top and bottom surfaces at the perimeter) may be inspected using the optical inspection device 114 and the light source 116 while the wafer stack 110 is on the chuck 108b. A controller 120b may be configured to cause the chuck 108b to rotate the wafer stack 110 while the light source 116 (positioned adjacent to the stage 106b) illuminates the perimeter of the wafer stack 110, and while the optical inspection device 114 (positioned adjacent to the stage 106b) generates images and/or video of the perimeter of the wafer stack 110.

If the controller 120b determines (e.g., based on the images and/or video of the perimeter of the wafer stack 110) that a rework operation is to be performed to rework the perimeter of the wafer stack 110, the controller 120b may provide one or more signals to cause the wafer/die transport tool to transfer the wafer stack 110 back to the chuck 108a on the stage 106a for rework. The controller 120a may provide one or more signals to the injector nozzle 112 to cause the injector nozzle 112 to dispense additional sealant into the groove around the perimeter of the wafer stack 110 (e.g., based on the controller 120b determining that an insufficient amount of sealant was dispensed into the groove), and/or may provide one or more signals to the scrubber device 118 to cause the scrubber device 118 to scrub the top and bottom surfaces of the perimeter of the wafers stack 110 (e.g., based on the controller 120b determining that sealant splash particles are located on the top and/or bottom surfaces of the perimeter of the wafers stack 110.

The controller 120a may then provide one or more signals to cause the wafer/die transport tool to transfer the wafer stack 110 back to the chuck 108b on the stage 106b for reinspection to verify that the rework operation(s) were completed successfully. In some implementations, instead of the semiconductor processing tool 102 including separate controllers 120a and 120b respectively for the stages 106a and 106b, the semiconductor processing tool 102 includes a single controller 120 for both the stages 106a and 106b.

As indicated above, FIG. 2 is provided as an example. Other examples may differ from what is described with regard to FIG. 2.

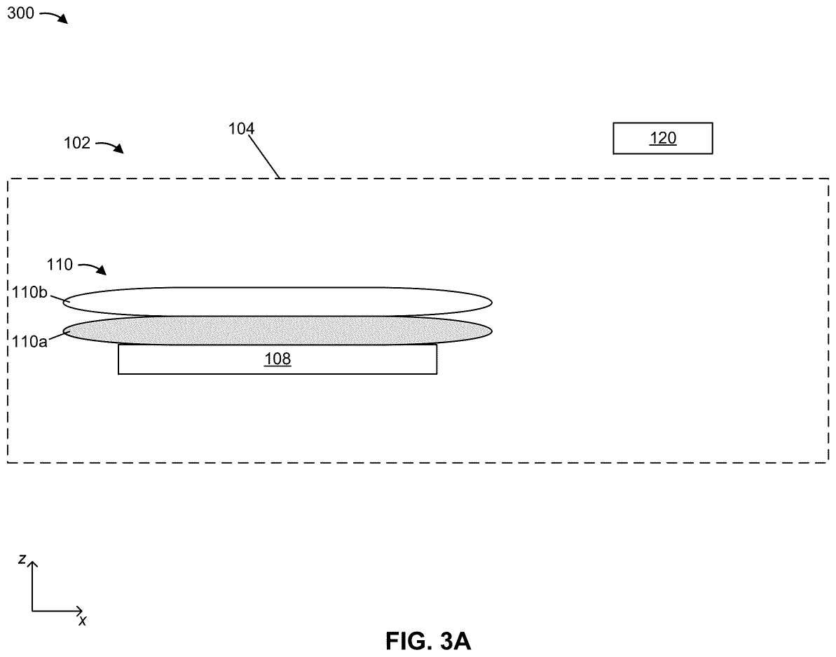

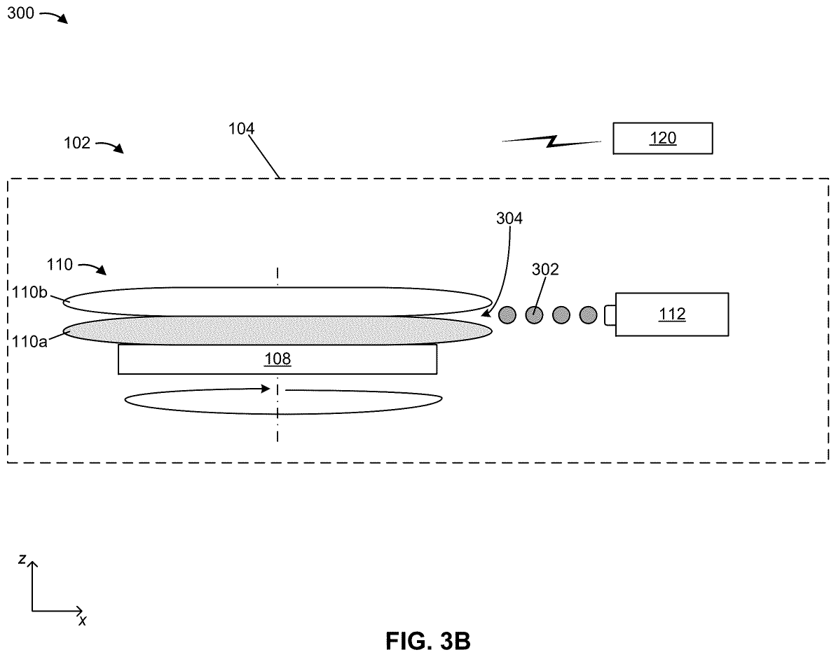

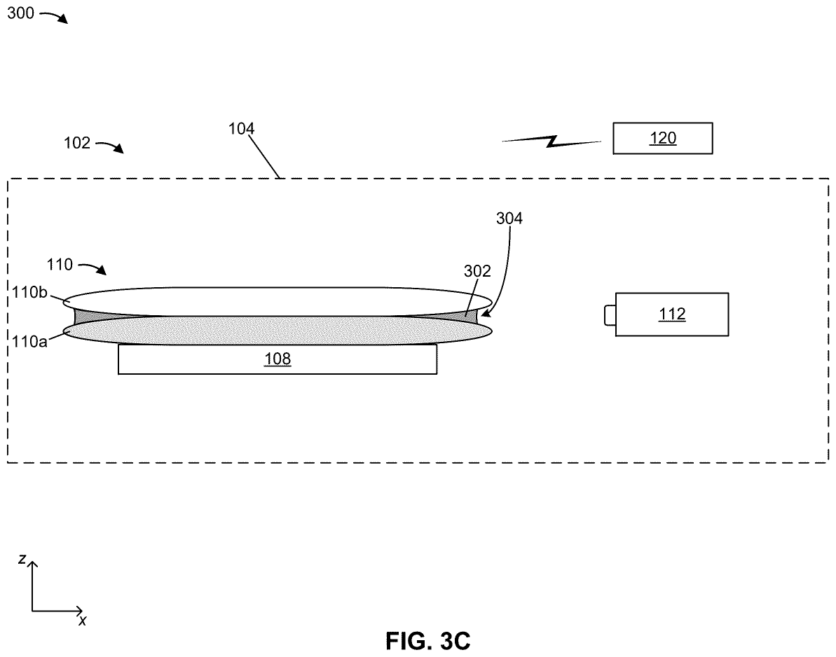

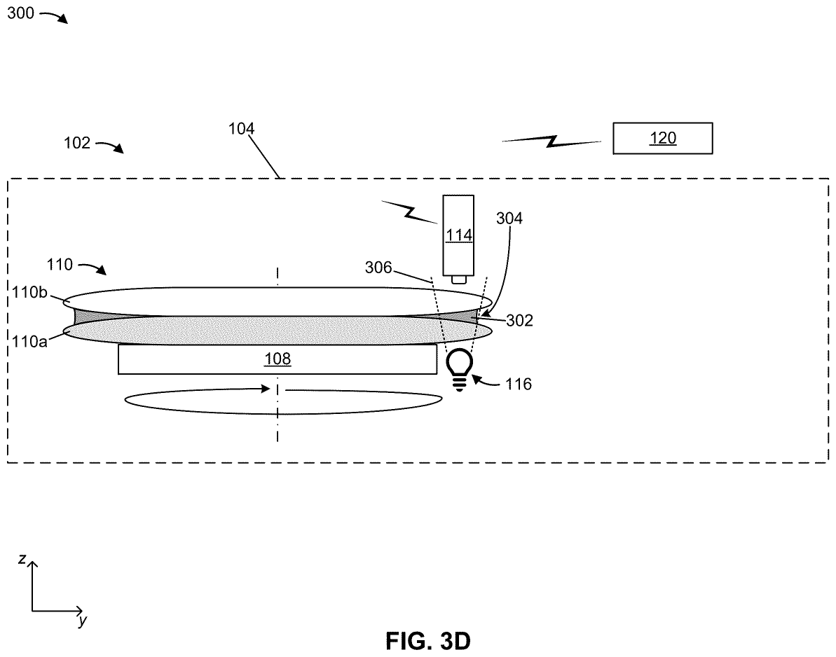

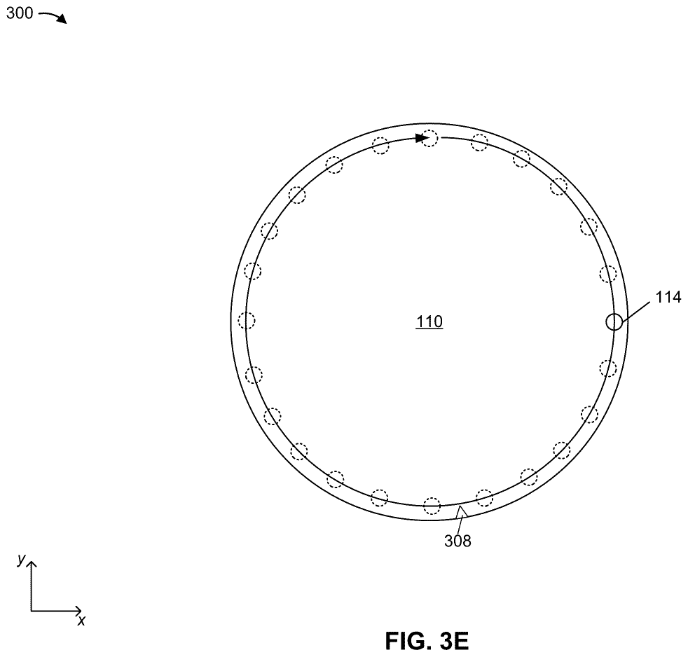

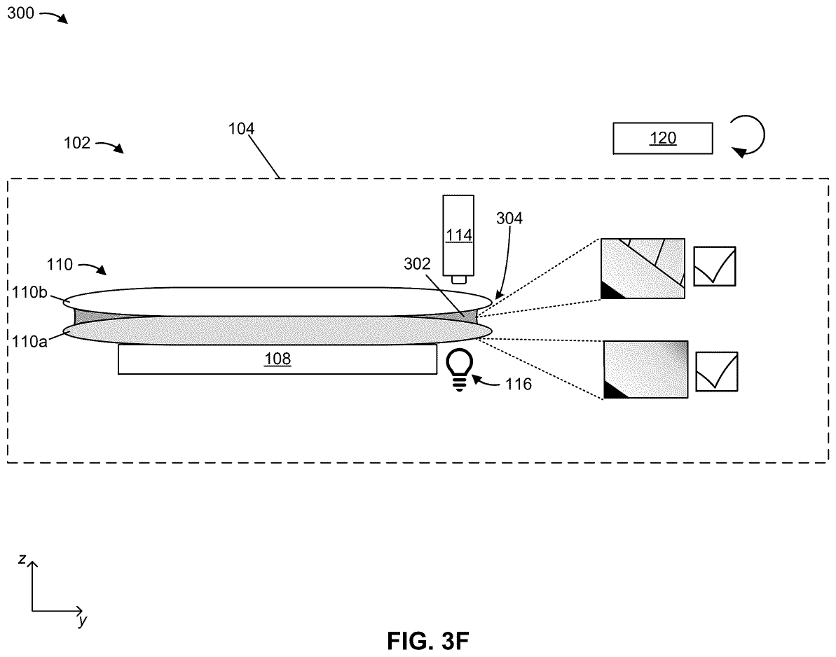

FIGS. 3A-3F are diagrams of an example implementation 300 of an edge sealing operation described herein. The edge sealing operation may be performed using the semiconductor processing tool 102 described herein. The edge sealing operation may be performed to dispense a sealant into a groove around a perimeter of a wafer stack 110 positioned on a chuck 108 in a processing chamber 104 of the semiconductor processing tool 102.

As shown in FIG. 3A, the wafer stack 110 may be received on the chuck 108 in the processing chamber 104. In some implementations, a wafer/die transport tool, such as a robot arm, may transfer the wafer stack 110 from a storage container (e.g., a front-opening unified pod (FOUP) and/or another type of wafer storage container) to the chuck 108.

As shown in FIG. 3B, the controller 120 may transmit one or more signals to the chuck 108 to cause the chuck 108 to rotate the wafer stack 110. The chuck 108 may rotate the wafer stack 110 about a central axis of the chuck 108. The controller 120 may transmit one or more signals to the injector nozzle 112 to cause the injector nozzle 112 to dispense a sealant 302 into a groove 304 around a perimeter of the wafer stack 110 during the sealant dispensing operation.

The groove 304 around a perimeter of the wafer stack 110 may correspond to a beveled region between the edges of stacked substrates 110a and 110b of the wafer stack 110. The substrates 110a and 110b may be bonded together at a bonding interface between surfaces of the substrates 110a and 110b, and the groove 304 may correspond to a non-bonded region between the substrates 110a and 110b where the curvatures in the surfaces of the substrates 110a and 110b cause the surfaces of the substrates 110a and 110b to diverge. In other words, the groove 304 may result from incomplete bonding between the edges of the substrates 110a and 110b due to curvatures in the surfaces of the substrates 110a and 110b at the edges of the substrates 110a and 110b.

The injector nozzle 112 may dispense the sealant 302 into the groove 304 around the perimeter of the wafer stack 110 while the chuck 108 rotates the wafer stack 110 so that the sealant 302 is dispensed into the groove 304 around the entire perimeter or circumference of the wafer stack 110. The sealant 302 protects the edges of the substrates 110a and 110b from ingress of contaminants through the groove 304 and/or reduces the likelihood of delamination of the substrates 110a and 110b starting from the groove 304.

The substrates 110a and 110b may each include a plurality of integrated circuit die products that are bonded together to form 3DIC assemblies. In some implementations, the substrates 110a and 110b include the same type or types of integrated circuit die products. For example, the substrates 110a and 110b may each include high-bandwidth memory dies (HBM dies) that are bonded together in a vertically stacked arrangement. In some implementations, the substrates 110a and 110b include different types of integrated circuit die products. For example, the substrate 110a may include logic dies and the substrate 110b may include memory dies, where the logic dies and the memory dies are bonded together in a vertically stacked arrangement. As another example, the substrate 110a may include CMOS image sensor dies and the substrate 110b may include application-specific integrated circuit (ASIC) dies, where the CMOS image sensor dies and the ASIC dies are bonded together in a vertically stacked arrangement.

The sealant 302 may include a low-viscosity material such as a dimethyldiethoxysilane (DMDEOS) compound, a tetraethyl orthosilicate (TEOS) compound, a polydimethylsiloxane (PDMS) compound, or a polysilazanes (PHPS) compound. In some implementations, the sealant 302 may include composite filler particulates such as silicon carbide (SiC) composite filler particulates, aluminum dioxide (Al₂O₃) composite filler particulates, zirconium tungsten phosphate (Zr₂WP₂O₁₂ or ZWP) composite filler particulates, silica (SiO₂) composite filler particulates, and/or ceramic composite particulates. Such composite filler particulates may improve a robustness of the sealant 302 and reduce a likelihood of tearing within the sealant 302.

As shown in FIG. 3C, the sealant 302 may fill in the groove 304 in the example implementation 300. The controller 120 may provide one or more signals to the chuck 108 to stop the chuck 108 from rotating the wafer stack 110 after the sealant 302 is dispensed into the groove 304. The controller 120 may also provide one or more signals to the injector nozzle 112 to stop the injector nozzle 112 from dispensing the sealant 302 into the groove 304.

As shown in FIG. 3D, the perimeter of the wafer stack 110 may be inspected after the sealant 302 is dispensed into the groove 304. The wafer stack 110 may be inspected while the wafer stack 110 is on the chuck 108. The controller 120 may transmit one or more signals to the light source 116 to cause the light source 116 to emit light 306. The light 306 may include infrared light, visible light, and/or another type of light. The light source 116 may project the light 306 through the perimeter of the wafer stack 110 and toward the optical inspection device 114.

The controller 120 may transmit one or more signals to the optical inspection device 114 to cause the optical inspection device 114 to generate one or more images and/or one or more videos based on the light 306 received at the optical inspection device 114. In particular, the optical inspection device 114 may generate images and/or videos of the perimeter of the wafer stack 110, including images and/or videos of the groove 304, the underside or bottom surface of the wafer stack 110, and/or the topside or top surface of the wafer stack 110.

In some implementations, the light source 116 is an infrared light source, and the optical inspection device 114 may generate infrared images and/or infrared videos of the perimeter of the wafer stack 110 based on the light 306 (e.g., infrared light) projected through the wafer stack 110. In some implementations, the light source 116 is a visible light source, and the optical inspection device 114 may generate images and/or infrared videos of the perimeter of the wafer stack 110 based on the light 306 (e.g., visible light) projected through the wafer stack 110.

FIG. 3E illustrates an example inspection path for inspecting the perimeter of the wafer stack 110. The optical inspection device 114 may be positioned at a fixed location above or below the wafer stack 110, and the chuck 108 may be used to rotate the wafer stack 110 so that the optical inspection device 114 generates images and/or videos at a plurality of locations along the circumference of the wafer stack 110. In some implementations, the optical inspection device 114 generates an image at particular angular locations along the circumference of the wafer stack 110. For example, the optical inspection device 114 may generate an image at every degree of rotation along the circumference of the wafer stack 110. As another example, the optical inspection device 114 may generate an image at every 5 degrees of rotation along the circumference of the wafer stack 110. The controller 120 may receive the images from the optical inspection device 114 and may index the images by angular or radial location relative to an alignment mark 308 on the wafer stack 110.

As shown in FIG. 3F, the controller 120 may determine whether any defects occurred during the edge sealing operation. In particular, the controller 120 may determine whether any defects occurred during the edge sealing operation based on the images and/or videos generated by the optical inspection device 114. The controller 120 may analyze an image of the perimeter of the wafer stack 110 to identify defects such as portions of the groove 304 in which an insufficient amount of sealant 302 was dispensed, and/or portions of the underside and/or topside of the wafer stack 110 on which sealant splash particles have been deposited.

To identify a portion of the groove 304 in which an insufficient amount of sealant 302 was dispensed, the controller 120 may use image recognition techniques to identify the sealant 302 in the groove 304. For example, the controller 120 may identify the sealant 302 in the groove 304 based on a difference in contrast in an image between the sealant 302 and the material of the wafer stack 110. In some implementations, the controller 120 determines that the sealant 302 has fully covered the groove 304 in an area along the perimeter of the wafer stack 110 based on an area of local contrast in the image spanning across the groove 304 between substrates 110a and 110b. In some implementations, the controller 120 determines that an insufficient amount of sealant 302 has been dispensed into the groove 304 in an area along the perimeter of the wafer stack 110 based on a difference in contrast between the sealant 302 in the area and the remainder of the area of the groove 304 in the area. In some implementations, the controller 120 uses an artificial intelligence model trained on a data set of images and/or videos (e.g., using machine learning) that depict grooves that contain various amount of sealant to determine whether a sufficient amount of sealant 302 has been dispensed into the groove 304.

To identify a portion of the perimeter of the wafer stack 110 that contains sealant splash particles, the controller 120 may use image recognition techniques to identify sealant splash particles on the underside and/or the topside of the wafer stack 110. For example, the controller 120 may identify a sealant splash particle based on a difference in contrast in an image between an area (that may or may not correspond to a sealant splash particle) and the underside of the wafer stack 110. The controller 120 may determine that the shape and/or the size of the area has a high likelihood of resembling a sealant splash particle.

In the example implementation 300, the controller 120 determines that a sufficient amount of sealant 302 was dispensed into the groove 304 around the perimeter of the wafer stack 110, and determines that no sealant splash particles have been identified on the underside and/or on the topside of the wafer stack 110. Accordingly, the controller 120 may transmit one or more signals to a wafer/die transport tool to retrieve the wafer stack 110 so that the wafer stack 110 can be transferred back to a storage container.

As indicated above, FIGS. 3A-3F are provided as an example. Other examples may differ from what is described with regard to FIGS. 3A-3F.

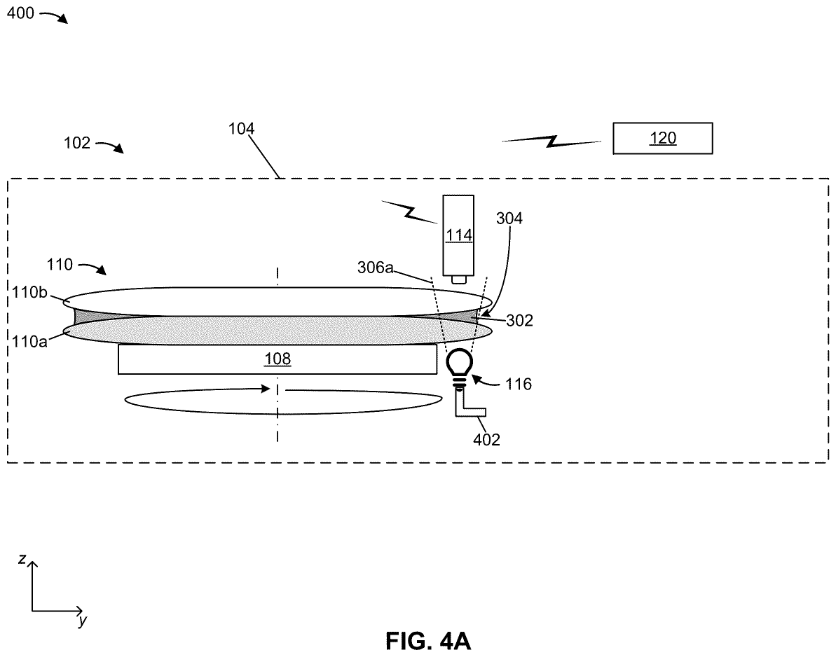

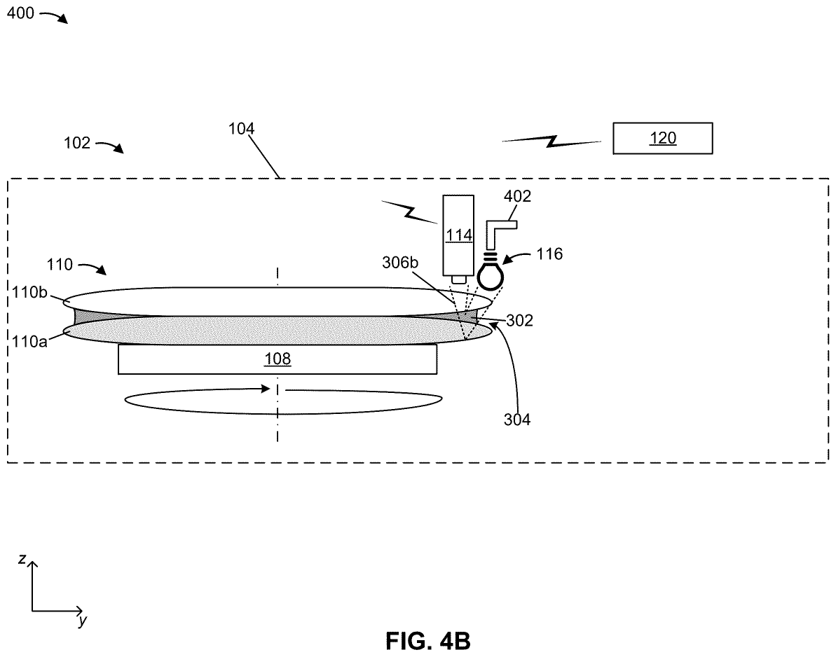

FIGS. 4A and 4B are diagrams of an example implementation 400 of an edge sealing inspection operation described herein. The edge sealing inspection operation may be performed using the semiconductor processing tool 102 described herein. The edge sealing inspection operation may be performed to inspect sealant 302 dispensed into a groove 304 around a perimeter of a wafer stack 110 to identify defects that may have occurred during an edge sealing operation for the wafer stack 110.

As shown in FIGS. 4A and 4B, the inspection techniques used in the example implementation 400 are similar to the inspection techniques used in the example implementation 300. However, in the example implementation 400, an articulating support arm 402 coupled to the light source 116 is used to move or rotate the light source 116 between different positions around the perimeter of the wafer stack 110.

For example, in FIG. 4A, the controller 120 transmits one or more signals to the articulating support arm 402 to cause the articulating support arm 402 to position the light source 116 below the wafer stack 110 so that the light source 116 projects light 306a through the perimeter of the wafer stack 110 and toward the optical inspection device 114. In this arrangement, the optical inspection device 114 generates images and/or video based on the light 306a transmitted through the wafer stack 110.

As another example, in FIG. 4B, the controller 120 transmits one or more signals to the articulating support arm 402 to cause the articulating support arm 402 to position the light source 116 above the wafer stack 110 so that the light source 116 projects light 306b onto the perimeter of the wafer stack 110. The light 306b is reflected off of the wafer stack 110 and toward the optical inspection device 114. In this arrangement, the optical inspection device 114 generates images and/or video based on the light 306b reflected off of the wafer stack 110.

In some implementations, the articulating support arm 402 rotates the light source 116 through an approximate 180 degree rotation path about the edge of the wafer stack 110 (e.g., in each angular inspection position). The optical inspection device 114 may generate an image and/or a video at various intermediate locations between 0 degrees of rotation and 180 degrees of rotation.

As indicated above, FIGS. 4A and 4B are provided as an example. Other examples may differ from what is described with regard to FIGS. 4A and 4B.

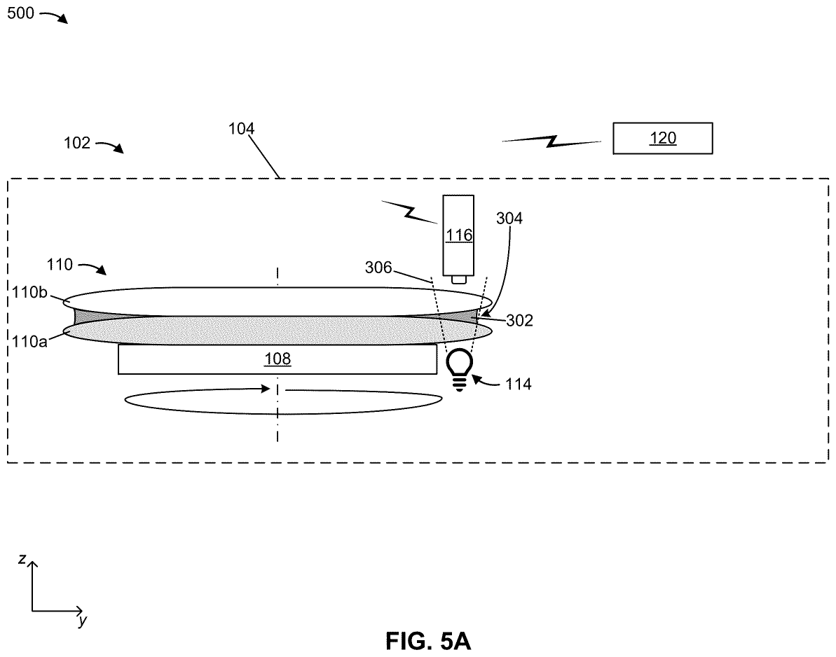

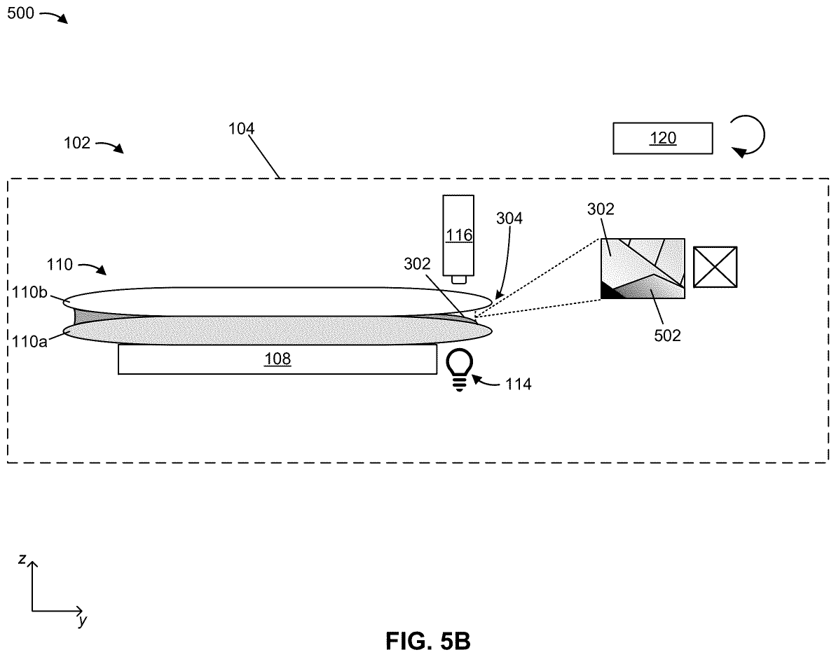

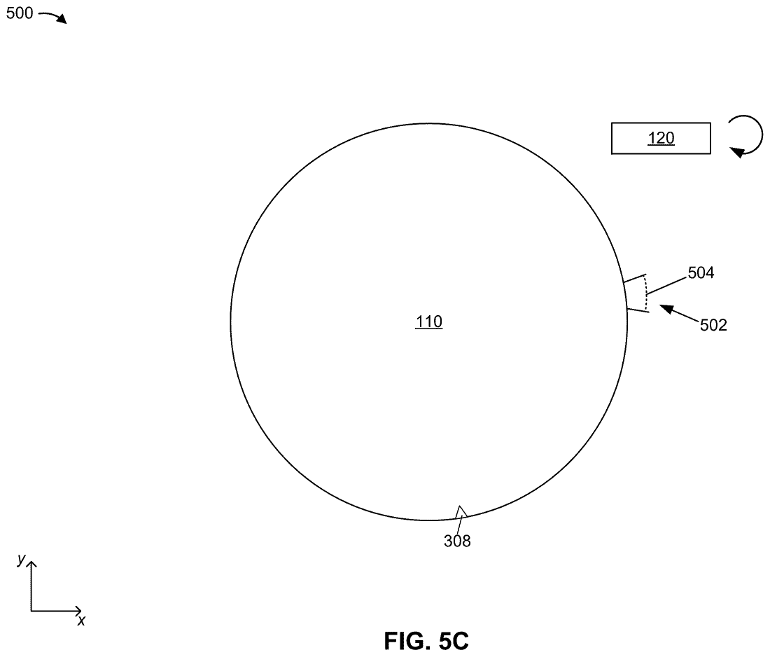

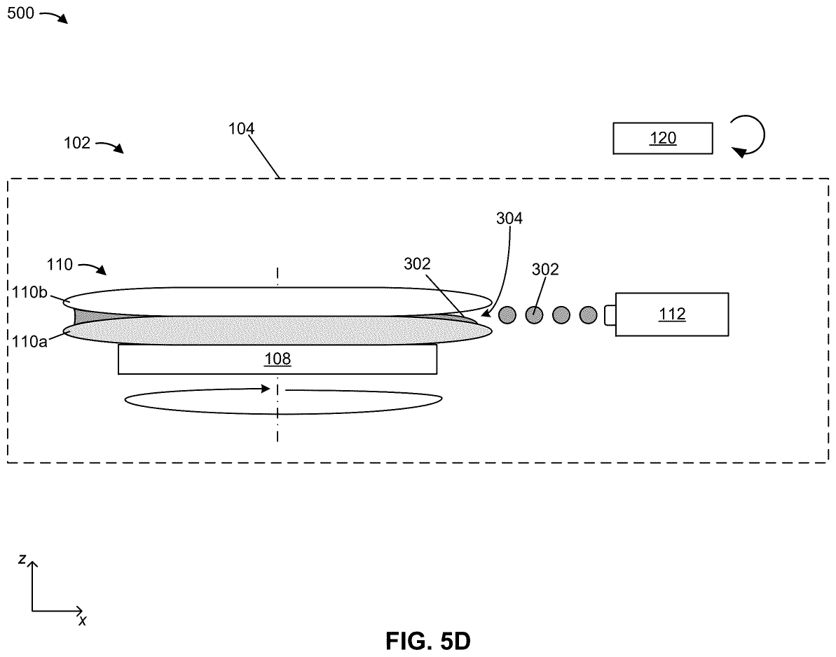

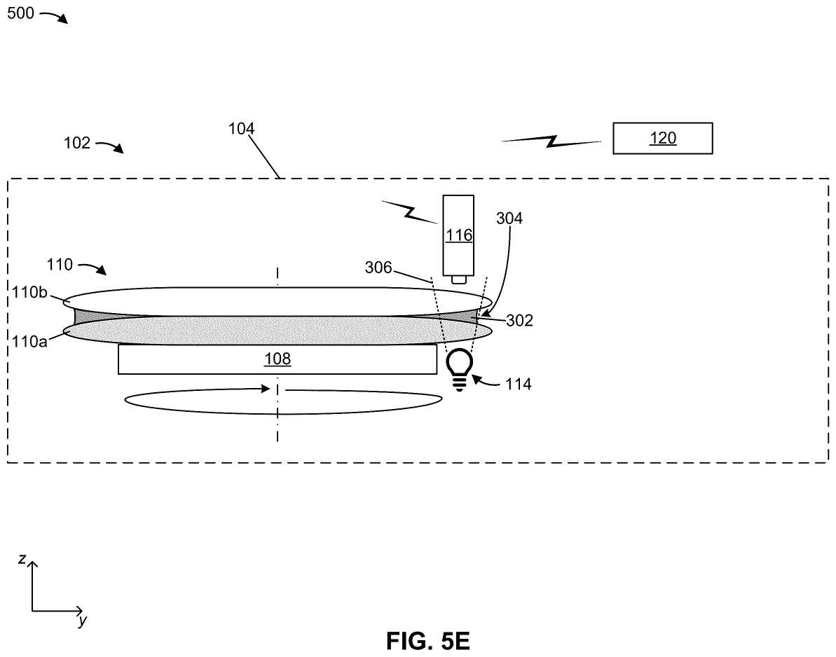

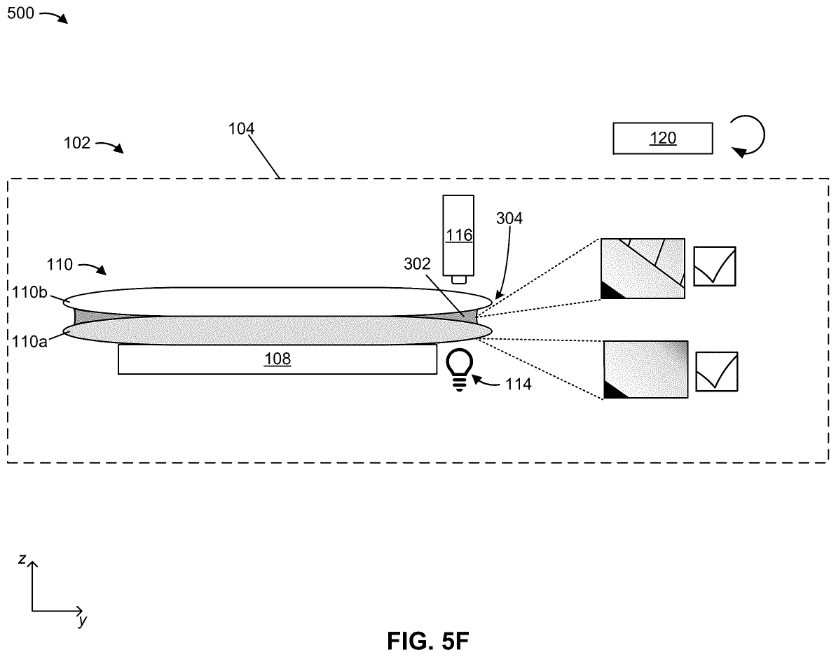

FIGS. 5A-5F are diagrams of an example implementation 500 of an edge sealing rework operation described herein. The edge sealing rework operation may be performed using the semiconductor processing tool 102 described herein. The edge sealing rework operation may be performed to rework the sealant 302 dispensed into a groove 304 at a perimeter of a wafer stack 110 to remove defects that may have occurred during an edge sealing operation for the wafer stack 110. An example edge sealing operation is illustrated and described in connection with FIGS. 3A-3F.

As shown in FIG. 5A, the perimeter of the wafer stack 110 may be inspected after the sealant 302 is dispensed into the groove 304. The wafer stack 110 may be inspected while the wafer stack 110 is on the chuck 108. The controller 120 may transmit one or more signals to the light source 116 to cause the light source 116 to emit light 306. The light 306 may include infrared light, visible light, and/or another type of light. The light source 116 may project the light 306 through the perimeter of the wafer stack 110 and toward the optical inspection device 114.

As shown in FIG. 5B, the controller 120 may identify a defect 502 at a location along the perimeter of the wafer stack 110 based on analyzing the images and/or videos generated by the optical inspection device 114. For example, the controller 120 may identify the defect 502 using one or more techniques described in connection with FIGS. 3A-3F. The defect 502 may correspond to a location along the perimeter of the wafer stack 110 in which the groove 304 has been partially filled with sealant 302. In other words, the defect 502 corresponds to a location along the perimeter of the wafer stack 110 in which an insufficient amount of sealant 302 was dispensed into the groove 304.

As shown in FIG. 5C, the controller 120 may identify a radial portion 504 along the circumference of the wafer stack 110 in which the defect 502 is located. The controller 120 may identify an angular location (e.g., in degrees, in radians) of the radial portion 504, which may be determined relative to the alignment mark 308 on the wafer stack 110. In some implementations, the controller 120 determines the angular location of the radial portion 504 based on the angular location indexed for the image or video in which the defect 502 was identified.

As shown in FIG. 5D, the controller 120 may cause a rework operation to be performed based on identifying the defect 502. In particular, the controller 120 may cause a rework operation to be performed to resolve the defect 502. For example, the controller 120 may transmit one or more signals to the chuck 108 to cause the chuck 108 to rotate the wafer stack 110, and the controller 120 may transmit one or more signals to the injector nozzle 112 to cause the injector nozzle 112 to dispense additional sealant 302 into the groove 304 to fill in the groove 304 in the location along the perimeter of the wafer stack 110 in which the groove 304 was partially filled with sealant 302. In some implementations, the chuck 108 rotates the wafer stack 110 for one or more full revolutions while the injector nozzle 112 dispenses additional sealant 302 into the groove 304. In some implementations, the chuck 108 rotates the wafer stack 110 so that the location along the perimeter of the wafer stack 110 in which the groove 304 was partially filled with sealant 302 is oriented toward the injector nozzle 112, so that the injector nozzle 112 dispenses additional sealant 302 into the groove 304 only in the location.

As shown in FIG. 5E, the perimeter of the wafer stack 110 may be reinspected after the rework operation was performed (e.g., after the additional sealant 302 is dispensed into the groove 304). The wafer stack 110 may be inspected while the wafer stack 110 is on the chuck 108. The controller 120 may transmit one or more signals to the light source 116 to cause the light source 116 to emit light 306. The light 306 may include infrared light, visible light, and/or another type of light. The light source 116 may project the light 306 through the perimeter of the wafer stack 110 and toward the optical inspection device 114.

As shown in FIG. 5F, the controller 120 may determine, based on the reinspection, that the defect 502 is no longer present and that no other defects are located along the perimeter of the wafer stack 110. Alternatively, if the controller 120 determines that the defect 502 is still located along the perimeter of the wafer stack 110 (or that new edge sealing defects are located along the perimeter of the wafer stack 110), the controller 120 may cause additional rework operations to be performed to resolve the defects.

As indicated above, FIGS. 5A-5F are provided as an example. Other examples may differ from what is described with regard to FIGS. 5A-5F.

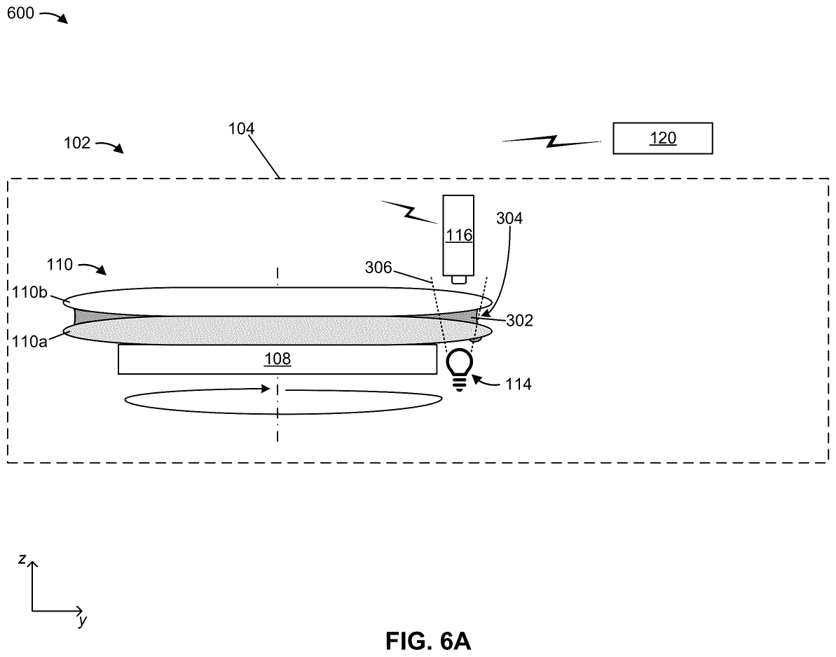

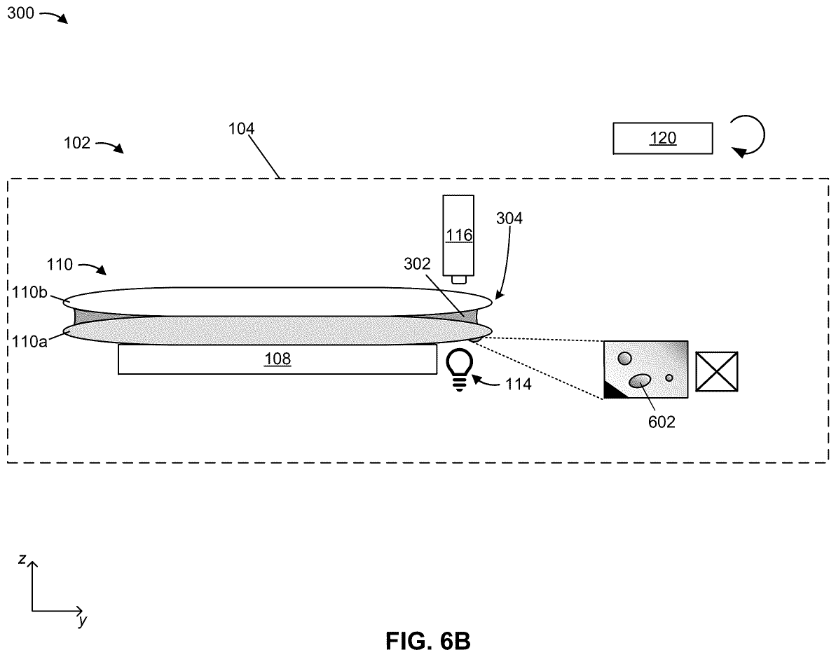

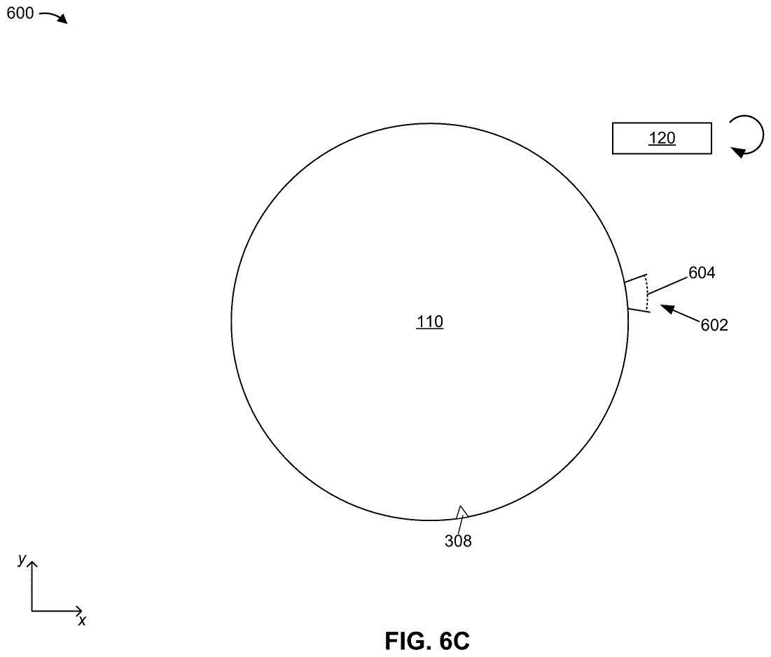

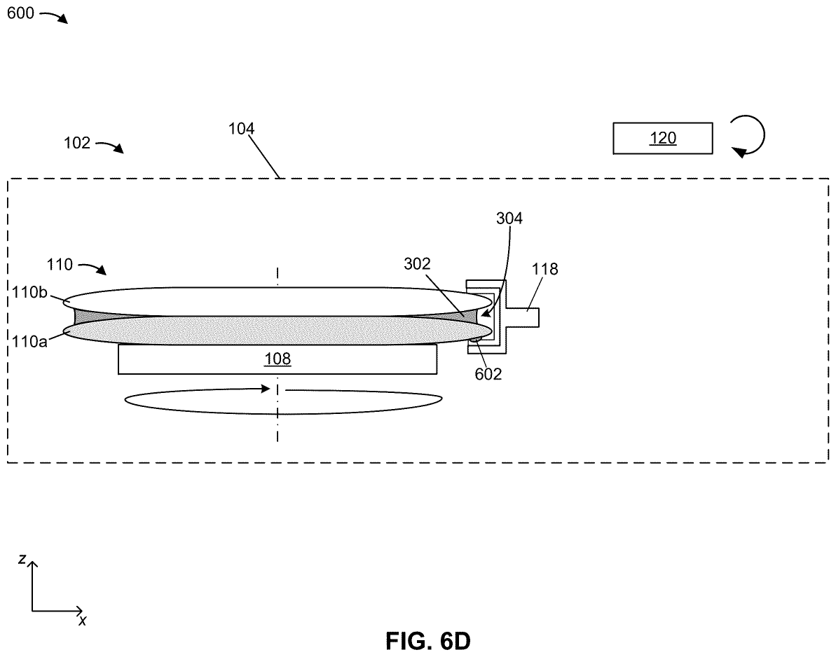

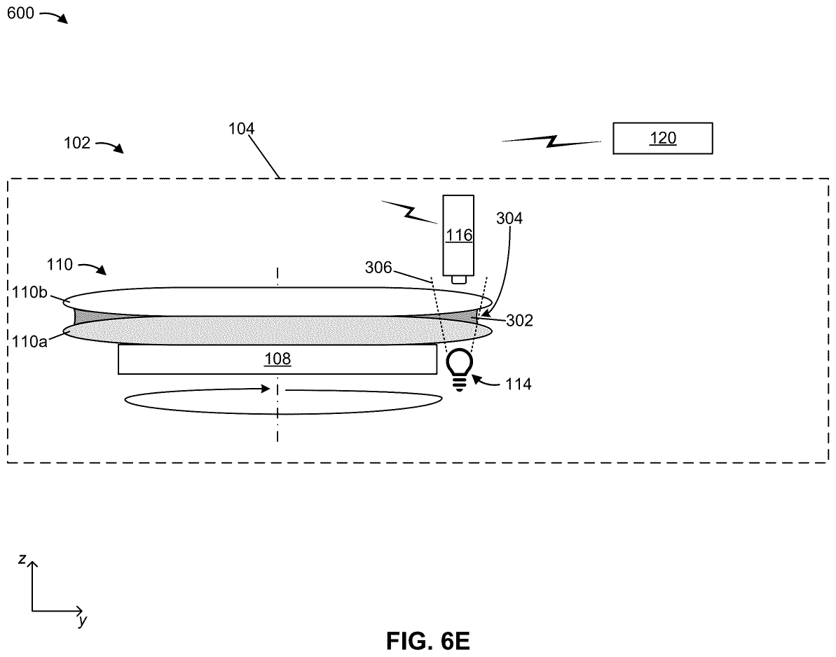

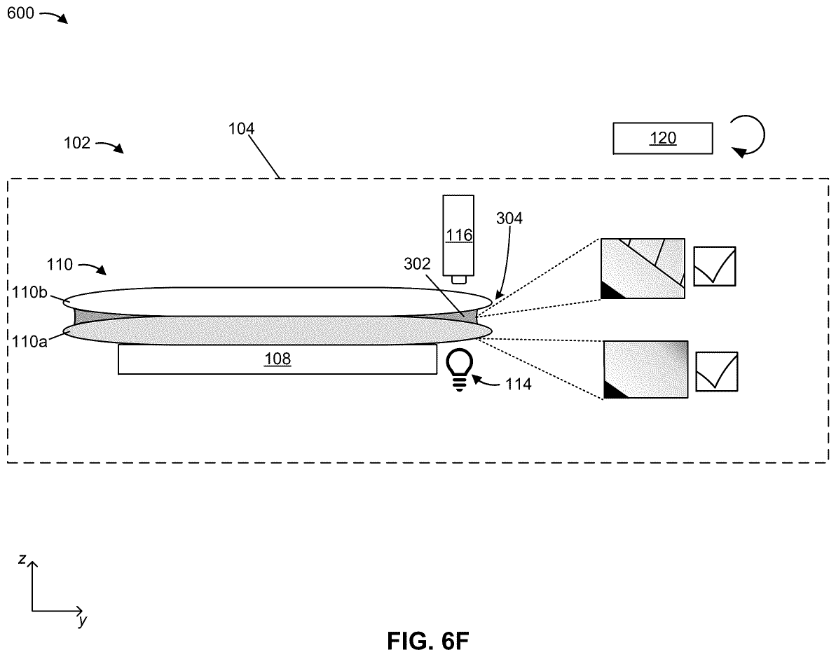

FIGS. 6A-6F are diagrams of an example implementation 600 of an edge sealing rework operation described herein. The edge sealing rework operation may be performed using the semiconductor processing tool 102 described herein. The edge sealing rework operation may be performed to rework the sealant 302 dispensed around a groove 304 at a perimeter of a wafer stack 110 to remove defects that may have occurred during an edge sealing operation for the wafer stack 110. An example edge sealing operation is illustrated and described in connection with FIGS. 3A-3F.

As shown in FIG. 6A, the perimeter of the wafer stack 110 may be inspected after the sealant 302 is dispensed into the groove 304. The wafer stack 110 may be inspected while the wafer stack 110 is on the chuck 108. The controller 120 may transmit one or more signals to the light source 116 to cause the light source 116 to emit light 306. The light 306 may include infrared light, visible light, and/or another type of light. The light source 116 may project the light 306 through the perimeter of the wafer stack 110 and toward the optical inspection device 114.

As shown in FIG. 6B, the controller 120 may identify a defect 602 at a location along the perimeter of the wafer stack 110 based on analyzing the images and/or videos generated by the optical inspection device 114. For example, the controller 120 may identify the defect 602 using one or more techniques described in connection with FIGS. 3A-3F. The defect 602 may correspond to a location along the perimeter of the wafer stack 110 in which one or more sealant splash particles have landed on the underside and/or on the topside of the perimeter of the wafer stack 110.

As shown in FIG. 6C, the controller 120 may identify a radial portion 604 along the circumference of the wafer stack 110 in which the defect 602 is located. The controller 120 may identify an angular location (e.g., in degrees, in radians) of the radial portion 604, which may be determined relative to the alignment mark 308 on the wafer stack 110. In some implementations, the controller 120 determines the angular location of the radial portion 604 based on the angular location indexed for the image or video in which the defect 602 was identified.

As shown in FIG. 6D, the controller 120 may cause a rework operation to be performed based on identifying the defect 602. In particular, the controller 120 may cause a rework operation to be performed to resolve the defect 602.

In some implementations, the controller 120 determines to cause the rework operation to be performed based on determining that the size of the defect 602 satisfies a size threshold. For example, the controller 120 may determine to cause the rework operation to be performed based on determining that a diameter of a sealant splash particle on the underside of the wafer stack 110 satisfies a diameter threshold. In some implementations, the diameter threshold is included in a range of approximately 1 micron to approximately 3 microns. However, other vales and ranges are within the scope of the present disclosure.

The controller 120 may determine the size of the defect 602 (e.g., of a sealant splash particle) using image analysis techniques such as pixel counting. For example, the controller 120 may identify a sealant splash particle in an image generated by the optical inspection device 114. The controller 120 may determine a quantity of pixels between the furthest points away on opposing sides of the sealant splash particle in the image. The controller 120 may determine the estimated distance between the furthest points based on the quantity of pixels, and this distance may correspond to the diameter of the sealant splash particle. Each pixel in the image may correspond to a particular unit of distance (e.g., 1 micron per pixel) that is based on the size of the pixels in the image, that is based on the distance between the wafer stack 110 and the optical inspection device 114, and/or that is based on another parameter.

To cause the rework operation to be performed, the controller 120 may transmit one or more signals to the chuck 108 to cause the chuck 108 to rotate the wafer stack 110, and the controller 120 may transmit one or more signals to the scrubber device 118 to cause the scrubber device 118 to be moved toward the edge of the wafer stack 110 so that the edge of the wafer stack is inserted into the scrubber device 118. The scrubber device 118 may scrub and/or otherwise mechanically remove the defect 602 from the wafer stack 110 while the chuck 108 rotates the wafer stack 110. In some implementations, the chuck 108 rotates the wafer stack 110 for one or more full revolutions while the scrubber device 118 scrubs the perimeter of the wafer stack 110. In some implementations, the chuck 108 rotates the wafer stack 110 so that the defect 602 is oriented toward the scrubber device 118, so that the scrubber device 118 scrubs the location of the defect 602.

As shown in FIG. 6E, the perimeter of the wafer stack 110 may be reinspected after the rework operation is performed (e.g., after the scrubber device 118 scrubs the perimeter of the wafer stack 110). The wafer stack 110 may be inspected while the wafer stack 110 is on the chuck 108. The controller 120 may transmit one or more signals to the light source 116 to cause the light source 116 to emit light 306. The light 306 may include infrared light, visible light, and/or another type of light. The light source 116 may project the light 306 through the perimeter of the wafer stack 110 and toward the optical inspection device 114.

As shown in FIG. 6F, the controller 120 may determine, based on the reinspection, that the defect 602 is no longer present and that no other defects are located along the perimeter of the wafer stack 110. Alternatively, if the controller 120 determines that the defect 602 is still located along the perimeter of the wafer stack 110 (or that new edge sealing defects are located along the perimeter of the wafer stack 110), the controller 120 may cause additional rework operations to be performed to resolve the defects.

As indicated above, FIGS. 6A-6F are provided as an example. Other examples may differ from what is described with regard to FIGS. 6A-6F.

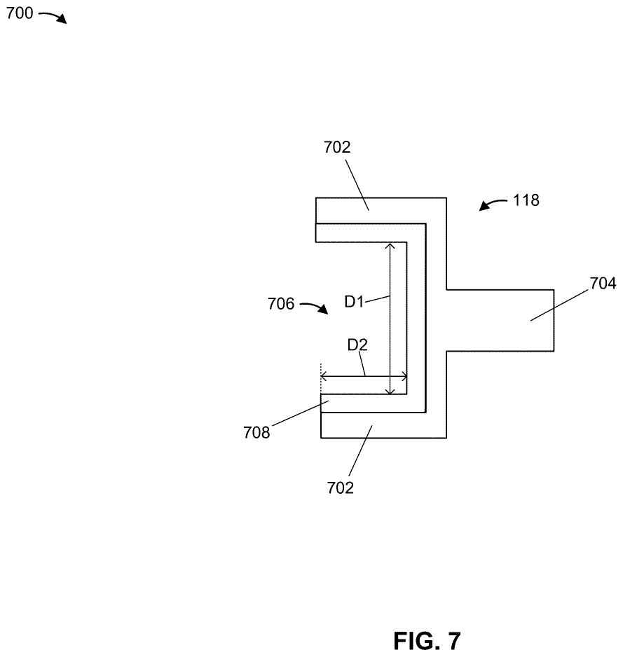

FIG. 7 is a diagram of an example implementation 700 of the scrubber device 118 described herein. As shown in FIG. 7, the scrubber device 118 may include upper and lower jaws 702 that extend from a support base 704. The jaws 702 may define an opening 706 in which a perimeter of wafer stack 110 may be inserted for scrubbing. The opening 706 may be lined with a cleaning device 708 such as a cleaning pad or a cleaning cloth.

A height of the opening 706 (indicated in FIG. 7 as a dimension D1) may be less than a thickness of the perimeter of the wafer stack 110. The height of the opening 706 enables the perimeter of the wafer stack 110 to be pressed against the cleaning device 708 for scrubbing. The cleaning device 708 may be formed of a soft material so as to not damage the wafer stack 110 during scrubbing.

A depth of the opening 706 (indicated in FIG. 7 as a dimension D2) may be sized to ensure that the cleaning device 708 extends toward a center of a wafer stack 110 by a sufficient amount to enable the perimeter of the wafer stack 110 to be cleaned, while preventing the edge of the wafer stack 110 from touching the cleaning device 708 (which might otherwise result in the cleaning device 708 removing sealant 302 from the groove 304 around the perimeter of the wafer stack 110).

As indicated above, FIG. 7 is provided as an example. Other examples may differ from what is described with regard to FIG. 7.

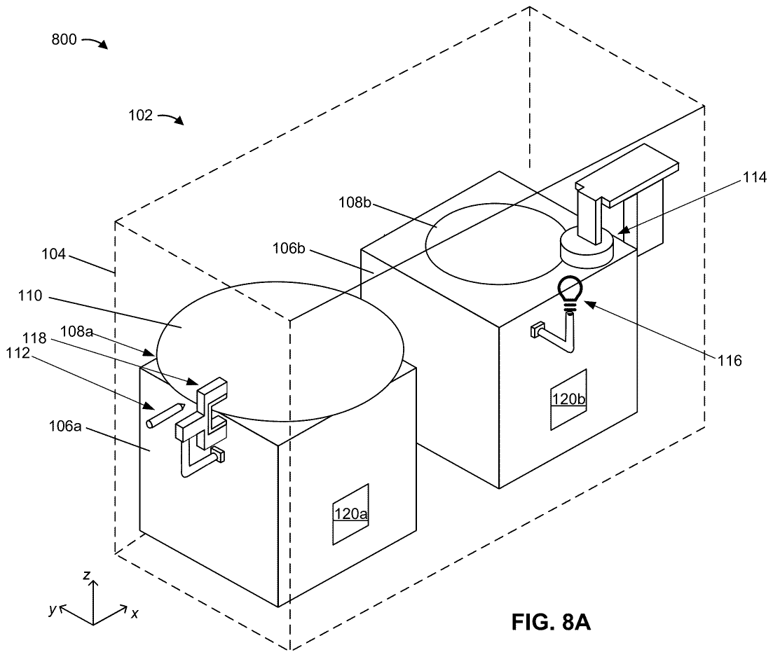

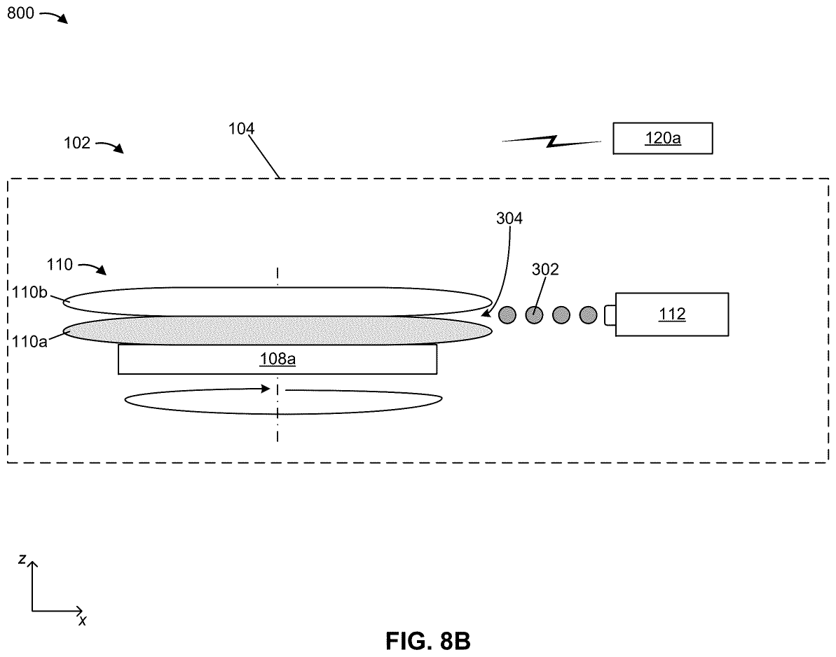

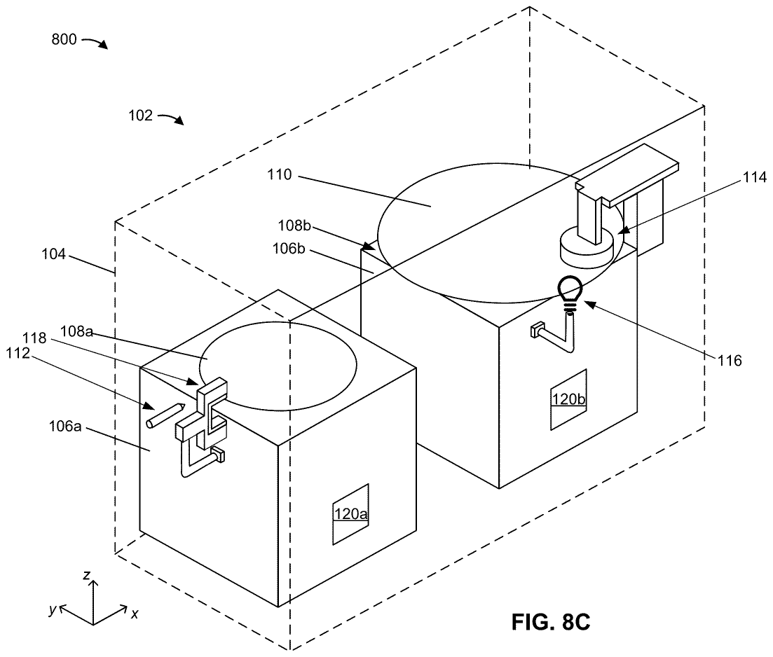

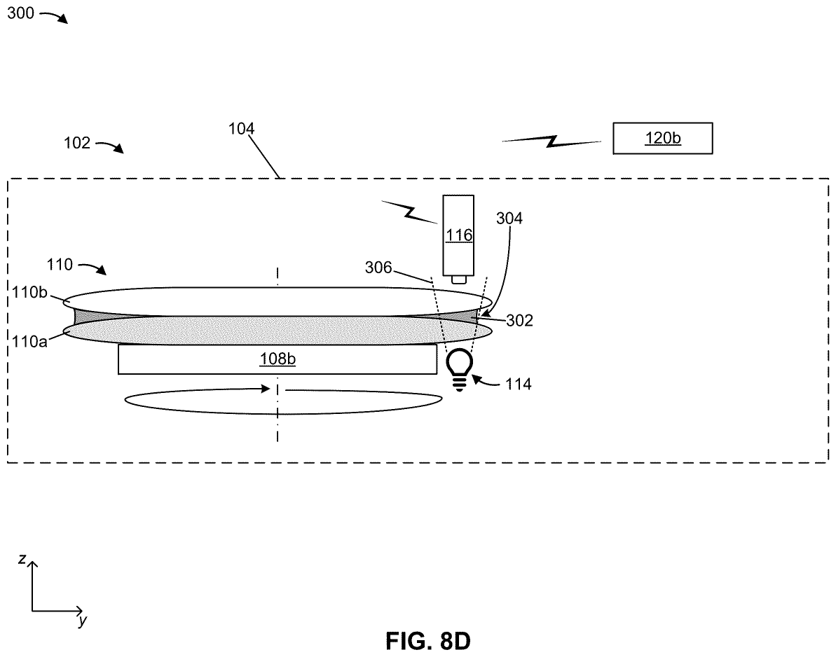

FIGS. 8A-8D are diagrams of an example implementation 800 of an edge sealing operation described herein. The edge sealing operation may be performed using the semiconductor processing tool 102 described herein. The edge sealing operation may be performed to dispense a sealant into a groove around a perimeter of a wafer stack 110 positioned on a chuck 108 in a processing chamber 104 of the semiconductor processing tool 102.

The edge sealing operation illustrated and described in the example implementation 800 is similar to the edge sealing operations illustrated and described in the example implementations 300, 400, 500, and/or 600. However, in the edge sealing operation illustrated and described in the example implementation 800, a wafer stack 110 is transferred between different stages 106a and 106b of the semiconductor processing tools 102 for sealant dispensing, inspection, and/or rework.

As shown in FIG. 8A, a wafer stack 110 may be received on the chuck 108a of the stage 106a in the processing chamber 104 of the semiconductor processing tool 102.

As shown in FIG. 8B, the controller 120a may transmit one or more signals to the chuck 108a to cause the chuck 108a rotate the wafer stack 110, and the controller 120a may transmit one or more signals to the injector nozzle 112 to cause the injector nozzle 112 to dispense the sealant 302 into the groove 304 around the perimeter of the wafer stack 110 while the chuck 108a rotates the wafer stack 110.

As shown in FIG. 8C, the wafer stack 110 may be transferred from the chuck 108a to the chuck 108b on the stage 106b after the sealant 302 is dispensed.

As shown in FIG. 8D, the controller 120b may transmit one or more signals to the chuck 108b to cause the chuck 108b to rotate the wafer stack 110. The controller 120b may transmit one or more signals to the light source 116 to cause the light source 116 to emit the light 306 toward the perimeter of the wafer stack 110 for inspection. The controller 120b may transmit one or more signals to the optical inspection device 114 to cause the optical inspection device 114 to inspect the perimeter of the wafer stack 110 (e.g., to generate images and/or videos of the perimeter of the wafer stack 110) while the chuck 108b rotates the wafer stack 110 and while the light source 116 illuminates the perimeter of the wafer stack 110.

If the controller 120b identifies one or more defects (e.g., defects 502, defects 602) in and/or around the groove 304 of the wafer stack 110, the controller 120b may cause the wafer stack 110 to be transferred back to the chuck 108a so that one or more rework operations may be performed on the wafer stack 110. For example, additional sealant 302 may be dispensed into the groove 304 based on the controller 120b determining that an insufficient amount of sealant 302 was dispensed into the groove 304. As another example, the scrubber device 118 may be used to scrub the perimeter of the wafer stack 110 to remove sealant splash particles from the underside and/or the topside of the perimeter of the wafer stack 110.

After rework, the controller 120a may cause the wafer stack 110 to be transferred back to the chuck 108b for reinspection.

As indicated above, FIGS. 8A-8D are provided as an example. Other examples may differ from what is described with regard to FIGS. 8A-8D.

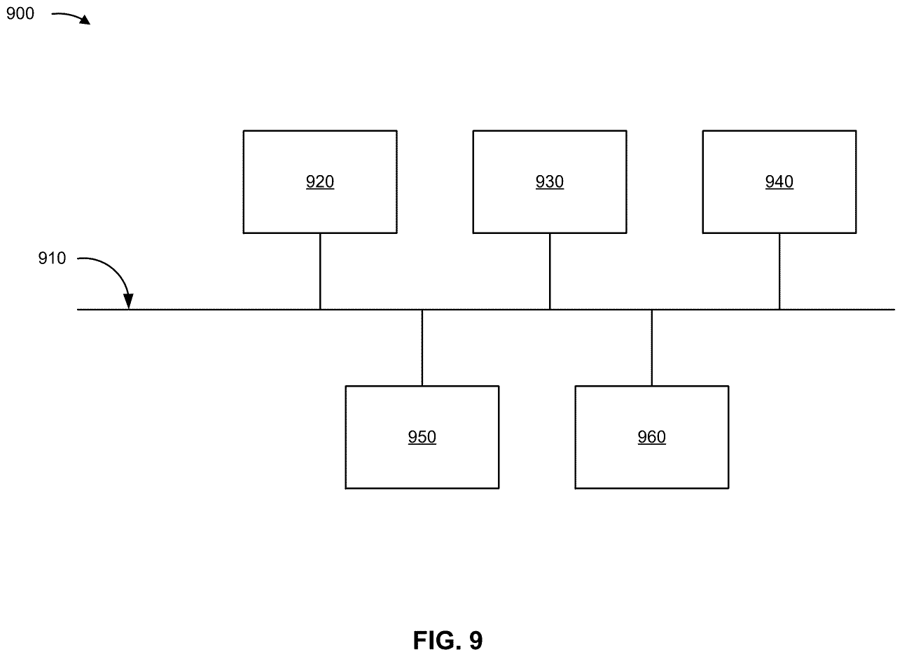

FIG. 9 is a diagram of example components of a device 900 described herein. The device 900 may correspond to the semiconductor processing tool 102 and/or one or more devices included therein, such as the stage 106 (or the stages 106a and 106b), the chuck 108 (or the chucks 108a and 108b), the injector nozzle 112, the optical inspection device 114, the light source 116, the scrubber device 118, and/or the controller 120 (or the controllers 120a and 120b), among other examples. In some implementations, the semiconductor processing tool 102 and/or one or more devices included therein, such as the stage 106 (or the stages 106a and 106b), the chuck 108 (or the chucks 108a and 108b), the injector nozzle 112, the optical inspection device 114, the light source 116, the scrubber device 118, and/or the controller 120 (or the controllers 120a and 120b) may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

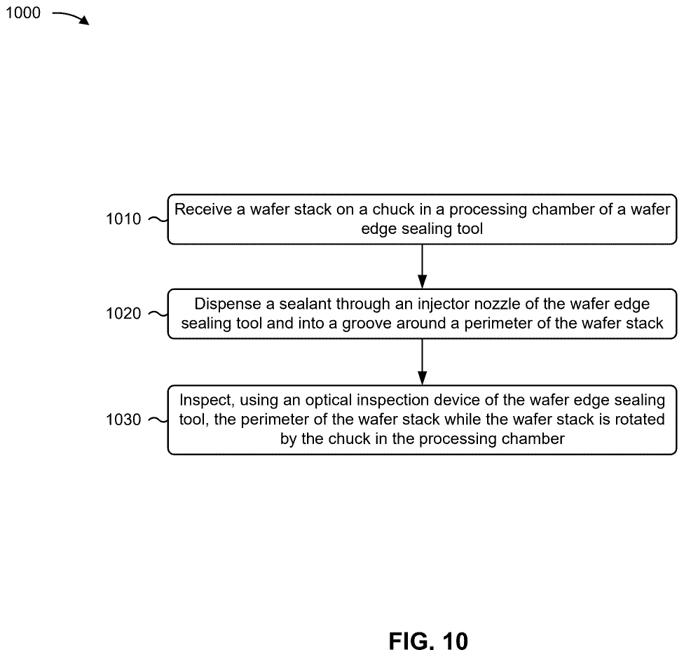

FIG. 10 is a flowchart of an example process 1000 associated with performing an edge sealing operation described herein. In some implementations, one or more process blocks of FIG. 10 are performed using a semiconductor processing tool (e.g., semiconductor processing tool 102). In some implementations, one or more process blocks of FIG. 10 are performed using another device or a group of devices separate from or including the semiconductor processing tool 102, such as a chuck (e.g., a chuck 108, a chuck 108a, a chuck 108b), an injector nozzle (e.g., an injector nozzle 112), an optical inspection device (e.g., optical inspection device 114), a light source (e.g., a light source 116), a scrubber device (e.g., a scrubber device 118), and/or a controller (e.g., a controller 120, a controller 120a, a controller 120b), among other examples. Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include receiving a wafer stack on a chuck in a processing chamber of a wafer edge sealing tool (block 1010). For example, the semiconductor processing tool 102 may be used to receive a wafer stack (e.g., a wafer stack 110) on a chuck (e.g., a chuck 108, a chuck 108a, a chuck 108b) in a processing chamber (e.g., a processing chamber 104) of the semiconductor processing tool 102 (e.g., a wafer edge sealing tool), as described herein.

As further shown in FIG. 10, process 1000 may include dispensing a sealant through an injector nozzle of the wafer edge sealing tool and into a groove around a perimeter of the wafer stack (block 1020). For example, the semiconductor processing tool 102 may be used to dispense a sealant (e.g., a sealant 302) through an injector nozzle (e.g., an injector nozzle 112) of the semiconductor processing tool 102 and into a groove (e.g., a groove 304) around a perimeter of the wafer stack, as described herein.

As further shown in FIG. 10, process 1000 may include inspecting, using an optical inspection device of the wafer edge sealing tool, the perimeter of the wafer stack while the wafer stack is rotated by the chuck in the processing chamber (block 1030). For example, the semiconductor processing tool 102 may be used to inspect, using an optical inspection device (e.g., an optical inspection device 114) of the semiconductor processing tool 102, the perimeter of the wafer stack while the wafer stack is rotated by the chuck in the processing chamber, as described herein.

Process 1000 may include additional implementations, such as any single implementation or any combination of implementations described below and/or in connection with one or more other processes described elsewhere herein.

In a first implementation, the optical inspection device includes an infrared camera positioned above the chuck.

In a second implementation, alone or in combination with the first implementation, inspecting the perimeter of the wafer stack includes projecting, using an infrared light source (e.g., a light source 116) in the processing chamber, infrared light (e.g., light 306) onto the perimeter of the wafer stack while the wafer stack is rotated by the chuck in the processing chamber, and using the infrared camera to generate an infrared image of the perimeter of the wafer stack based on the infrared light.

In a third implementation, alone or in combination with one or more of the first and second implementations, a wavelength of the infrared light is included in a range of approximately 800 nanometers to approximately 1300 nanometers.

In a fourth implementation, alone or in combination with one or more of the first through third implementations, the infrared light source is positioned under the wafer stack.

In a fifth implementation, alone or in combination with one or more of the first through fourth implementations, inspecting the perimeter of the wafer stack includes projecting the infrared light onto the perimeter of the wafer stack while the infrared light source is positioned under the wafer stack, and projecting the infrared light onto the perimeter of the wafer stack while the infrared light source is positioned above the wafer stack.

In a sixth implementation, alone or in combination with one or more of the first through fifth implementations, inspecting the perimeter of the wafer stack includes moving, using an articulating support arm (e.g., an articulating support arm 402), the infrared light source between being positioned under the wafer stack and being positioned above the wafer stack.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

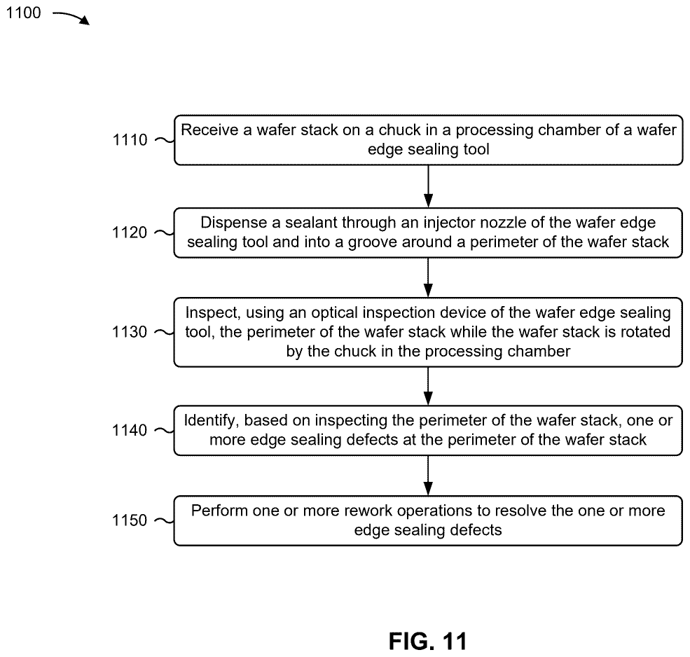

FIG. 11 is a flowchart of an example process 1100 associated with performing an edge sealing operation described herein. In some implementations, one or more process blocks of FIG. 11 are performed using a semiconductor processing tool (e.g., semiconductor processing tool 102). In some implementations, one or more process blocks of FIG. 11 are performed using another device or a group of devices separate from or including the semiconductor processing tool 102, such as a chuck (e.g., a chuck 108, a chuck 108a, a chuck 108b), an injector nozzle (e.g., an injector nozzle 112), an optical inspection device (e.g., optical inspection device 114), a light source (e.g., a light source 116), a scrubber device (e.g., a scrubber device 118), and/or a controller (e.g., a controller 120, a controller 120a, a controller 120b), among other examples. Additionally, or alternatively, one or more process blocks of FIG. 11 may be performed by one or more components of device 900, such as processor 920, memory 930, input component 940, output component 950, and/or communication component 960.

As shown in FIG. 11, process 1100 may include receiving a wafer stack on a chuck in a processing chamber of a wafer edge sealing tool (block 1110). For example, the semiconductor processing tool 102 may be used to receive a wafer stack (e.g., a wafer stack 110) on a chuck (e.g., a chuck 108, a chuck 108a, a chuck 108b) in a processing chamber (e.g., a processing chamber 104) of a wafer edge sealing tool (e.g., a semiconductor processing tool 102), as described herein.

As further shown in FIG. 11, process 1100 may include dispensing a sealant through an injector nozzle wafer edge sealing tool and into a groove around a perimeter of the wafer stack (block 1120). For example, the semiconductor processing tool 102 may be used to dispense a sealant (e.g., a sealant 302) through an injector nozzle (e.g., an injector nozzle 112) of the wafer edge sealing tool and into a groove (e.g., a groove 304) around a perimeter of the wafer stack, as described herein.

As further shown in FIG. 11, process 1100 may include inspecting, using an optical inspection device of the wafer edge sealing tool, the perimeter of the wafer stack while the wafer stack is rotated by the chuck in the processing chamber (block 1130). For example, the semiconductor processing tool 102 may be used to inspect, using an optical inspection device (e.g., an optical inspection device 114) of the wafer edge sealing tool, the perimeter of the wafer stack while the wafer stack is rotated by the chuck in the processing chamber, as described herein.

As further shown in FIG. 11, process 1100 may include identifying, based on inspecting the perimeter of the wafer stack, one or more edge sealing defects at the perimeter of the wafer stack (block 1140). For example, the semiconductor processing tool 102 may be used to identify, based on inspecting the perimeter of the wafer stack, one or more edge sealing defects (e.g., a defect 502, a defect 602) at the perimeter of the wafer stack, as described herein.

As further shown in FIG. 11, process 1100 may include performing one or more rework operations to resolve the one or more edge sealing defects (block 1150). For example, the semiconductor processing tool 102 may perform one or more rework operations to resolve the one or more edge sealing defects, as described herein.

Process 1100 may include additional implementations, such as any single implementation or any combination of implementations described below and/or in connection with one or more other processes described elsewhere herein.

In a first implementation, identifying the one or more edge sealing defects includes determining that the groove has been partially filled with the sealant, and performing the one or more rework operations includes performing a re-sealing operation to dispense additional sealant into the groove.

In a second implementation, alone or in combination with the first implementation, process 1100 includes reinspecting, using the optical inspection device, the perimeter of the wafer stack after performing the re-sealing operation.

In a third implementation, alone or in combination with one or more of the first and second implementations, determining that the groove has been partially filled with the sealant includes identifying a radial portion (e.g., a radial portion 504) of the perimeter in which the groove has been partially filled with the sealant.

In a fourth implementation, alone or in combination with one or more of the first through third implementations, identifying the one or more edge sealing defects includes identifying sealant splash particles (e.g., a defect 602) on an underside of the wafer stack, and performing the one or more rework operations includes performing a perimeter cleaning operation to remove at least a subset of the sealant splash particles from the underside of the wafer stack.

In a fifth implementation, alone or in combination with one or more of the first through fourth implementations, process 1100 includes reinspecting, using the optical inspection device, the perimeter of the wafer stack after performing the perimeter cleaning operation.

In a sixth implementation, alone or in combination with one or more of the first through fifth implementations, identifying the sealant splash particles on the underside of the wafer stack includes identifying a radial portion (e.g., a radial portion 504) of the perimeter in which the sealant splash particles are located on the underside of the wafer stack.

In a seventh implementation, alone or in combination with one or more of the first through sixth implementations, performing the perimeter cleaning operation includes performing the perimeter cleaning operation using an edge scrubber device (e.g., a scrubber device 118).

In an eighth implementation, alone or in combination with one or more of the first through seventh implementations, performing the perimeter cleaning operation using the edge scrubber device includes inserting the perimeter of the wafer stack into an opening (e.g., an opening 706) defined by jaws (e.g., jaws 702) of the edge scrubber device so that the perimeter of the wafer stack is in contact with a cleaning pad (e.g., a cleaning device 708) supported by the jaws, and rotating the wafer stack using the chuck so that the cleaning pad scrubs the perimeter of the wafer stack.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a sealant inspection system for use with a wafer edge sealing tool includes one or more devices that are configured to inspect the sealant dispensed into and/or around the groove around a wafer stack. The sealant inspection system may determine whether a sufficient amount of sealant is dispensed into the groove and/or whether errant sealant particles landed on the top and/or bottom surfaces of the wafer stack. This enables the sealant inspection system to cause a reseal operation to be performed to dispense additional sealant into the groove if an insufficient amount of sealant was dispensed into the groove, and/or enables the sealant inspection system to cause a cleaning operation to be performed to clean the top and/or bottom surfaces of the wafer stack. In this way, the sealant inspection system prevents, minimizes, and/or otherwise reduces the likelihood of delamination of the wafer stack and/or errant sealant particles causing defects in subsequent processing operations. Moreover, the sealant inspection system enables rework of the wafer stack to be performed in a more timely manner, thereby reducing processing delays for the wafer stack and/or increasing the likelihood that the wafer stack can be saved from being scrapped.

As described in greater detail above, some implementations described herein provide a method. The method includes receiving a wafer stack on a chuck in a processing chamber of a wafer edge sealing tool. The method includes dispensing a sealant through an injector nozzle of the wafer edge sealing tool and into a groove around a perimeter of the wafer stack. The method includes inspecting, using an optical inspection device of the wafer edge sealing tool, the perimeter of the wafer stack while the wafer stack is rotated by the chuck in the processing chamber.

As described in greater detail above, some implementations described herein provide a method. The method includes receiving a wafer stack on a chuck in a processing chamber of a wafer edge sealing tool. The method includes dispensing a sealant through an injector nozzle of the wafer edge sealing tool and into a groove around a perimeter of the wafer stack. The method includes inspecting, using an optical inspection device of the wafer edge sealing tool, the perimeter of the wafer stack while the wafer stack is rotated by the chuck in the processing chamber. The method includes identifying, based on inspecting the perimeter of the wafer stack, one or more edge sealing defects at the perimeter of the wafer stack. The method includes performing one or more rework operations to resolve the one or more edge sealing defects.

As described in greater detail above, some implementations described herein provide a wafer edge sealing tool. The wafer edge sealing tool includes a processing chamber. The wafer edge sealing tool includes a chuck in the processing chamber, where the chuck is configured to support a wafer stack. The wafer edge sealing tool includes an injector nozzle laterally adjacent to the chuck in the processing chamber, where the injector nozzle is configured to dispense a sealant. The wafer edge sealing tool includes an edge scrubber device laterally adjacent to the chuck in the processing chamber, where the edge scrubber device is configured to clean a perimeter of the wafer stack.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving a wafer stack on a chuck in a processing chamber of a wafer edge sealing tool;
dispensing a sealant through an injector nozzle of the wafer edge sealing tool and into a groove around a perimeter of the wafer stack; and
inspecting, using an optical inspection device of the wafer edge sealing tool, the perimeter of the wafer stack while the wafer stack is rotated by the chuck in the processing chamber.

2. The method of claim 1, wherein the optical inspection device comprises an infrared camera positioned above the chuck.

3. The method of claim 2, wherein inspecting the perimeter of the wafer stack comprises:
projecting, using an infrared light source in the processing chamber, infrared light onto the perimeter of the wafer stack while the wafer stack is rotated by the chuck in the processing chamber; and
using the infrared camera to generate an infrared image of the perimeter of the wafer stack based on the infrared light.

4. The method of claim 3, wherein a wavelength of the infrared light is included in a range of approximately 800 nanometers to approximately 1300 nanometers.

5. The method of claim 3, wherein the infrared light source is positioned under the wafer stack.

6. The method of claim 3, wherein the inspecting the perimeter of the wafer stack comprises:
projecting the infrared light onto the perimeter of the wafer stack while the infrared light source is positioned under the wafer stack; and
projecting the infrared light onto the perimeter of the wafer stack while the infrared light source is positioned above the wafer stack.

7. The method of claim 6, wherein inspecting the perimeter of the wafer stack comprises:
moving, using an articulating support arm, the infrared light source between being positioned under the wafer stack and being positioned above the wafer stack.

8. A method, comprising:
receiving a wafer stack on a chuck in a processing chamber of a wafer edge sealing tool;
dispensing a sealant through an injector nozzle of the wafer edge sealing tool and into a groove around a perimeter of the wafer stack;
inspecting, using an optical inspection device of the wafer edge sealing tool, the perimeter of the wafer stack while the wafer stack is rotated by the chuck in the processing chamber;
identifying, based on inspecting the perimeter of the wafer stack, one or more edge sealing defects at the perimeter of the wafer stack; and
performing one or more rework operations to resolve the one or more edge sealing defects.

9. The method of claim 8, wherein identifying the one or more edge sealing defects comprises:
determining that the groove has been partially filled with the sealant; and
wherein performing the one or more rework operations comprises:
performing a re-sealing operation to dispense additional sealant into the groove.

10. The method of claim 9, further comprising:
reinspecting, using the optical inspection device, the perimeter of the wafer stack after performing the re-sealing operation.

11. The method of claim 9, wherein determining that the groove has been partially filled with the sealant comprises:
identifying a radial portion of the perimeter in which the groove has been partially filled with the sealant.

12. The method of claim 8, wherein identifying the one or more edge sealing defects comprises:
identifying sealant splash particles on an underside of the wafer stack; and
wherein performing the one or more rework operations comprises:
performing a perimeter cleaning operation to remove at least a subset of the sealant splash particles from the underside of the wafer stack.

13. The method of claim 12, further comprising:
reinspecting, using the optical inspection device, the perimeter of the wafer stack after performing the perimeter cleaning operation.

14. The method of claim 12, wherein identifying the sealant splash particles on the underside of the wafer stack comprises:
identifying a radial portion of the perimeter in which the sealant splash particles are located on the underside of the wafer stack.

15. The method of claim 12, wherein performing the perimeter cleaning operation comprises:
performing the perimeter cleaning operation using an edge scrubber device.

16. The method of claim 15, wherein performing the perimeter cleaning operation using the edge scrubber device comprises:
inserting the perimeter of the wafer stack into an opening defined by jaws of the edge scrubber device so that the perimeter of the wafer stack is in contact with a cleaning pad supported by the jaws; and
rotating the wafer stack using the chuck so that the cleaning pad scrubs the perimeter of the wafer stack.

17. A wafer edge sealing tool, comprising:
a processing chamber;
a chuck in the processing chamber,
wherein the chuck is configured to support a wafer stack;
an injector nozzle laterally adjacent to the chuck in the processing chamber,
wherein the injector nozzle is configured to dispense a sealant; and
an edge scrubber device laterally adjacent to the chuck in the processing chamber,
wherein the edge scrubber device is configured to clean a perimeter of the wafer stack.

18. The wafer edge sealing tool of claim 17, further comprising:
an optical inspection device vertically adjacent to the chuck in the processing chamber; and
a light source vertically adjacent to the chuck in the processing chamber.

19. The wafer edge sealing tool of claim 18, wherein the light source is supported by an articulating support arm in the processing chamber.

20. The wafer edge sealing tool of claim 17, wherein the chuck comprises a first chuck; and
wherein the wafer edge sealing tool further comprises:
a second chuck in the processing chamber;
an optical inspection device vertically adjacent to the second chuck in the processing chamber; and
a light source vertically adjacent to the second chuck in the processing chamber.
